(19) United States
(12) Patent Application Publication
(10) Pub. No.: US 2007/0145895 A1
(43) Pub. Date: Jun. 28, 2007

(54) LIGHT EMITTING APPARATUS, EXPOSURE APPARATUS, AND METHOD FOR MANUFACTURING LIGHT EMITTING APPARATUS

(75) Inventors: Shinya YAMAMOTO, Fukuoka (JP); Kei SAKANOUE, Fukuoka (JP); Ryuuichi YATSUNAMI, Fukuoka (JP); Naoto MATSUO, Fukuoka (JP); Takafumi HAMANO, Fukuoka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/548,375

(22) Filed: Oct. 11, 2006

(30) Foreign Application Priority Data
Oct. 14, 2005 (JP) 2005/300039

(51) Int. Cl. H01J 1/62

(52) U.S. Cl. 313/512

(57) ABSTRACT

There is provided a light emitting apparatus for which sealing can be carried out with a simple step using a thermosetting resin as a material for a sealing part, and which has ensured a sufficient gas barrier property without damaging an organic electroluminescence element by heat, and further while using a simple sealing step. The apparatus was configured so as to have a substrate 2, a plurality of light emitting parts formed using a polymer organic electroluminescence material formed on the substrate 2, an electrode (cathode 7) covering the light emitting parts LS, and a sealing part 10 including a thermosetting resin, covering at least the wider region than this electrode (cathode 7).

### BACKGROUND OF THE INVENTION

1. Field of the Invention

The present invention relates to a light emitting apparatus provided with organic electroluminescence elements, an exposure apparatus including the light emitting apparatus built therein, and an image forming apparatus mounting therein the exposure apparatus.

2. Description of the Related Art

An electroluminescence element is a light emitting device utilizing the electroluminescence of a solid fluorescent substance, and currently, an inorganic electroluminescence element using an inorganic type material as an illuminant has come into a practical use. Thus, its application and development into the backlight in a liquid crystal display, a flat display, or the like have been made in some quarters. However, for the inorganic electroluminescence element, the voltage required for light emission is as high as 100 V or more, and further, blue light emission is difficult. Therefore, full color exhibition with three primary colors of R, G, and B is difficult to implement. Further, for the inorganic electroluminescence element, the refractive index of the material for use as an illuminant is very large. For this reason, the inorganic electroluminescence element is strongly affected by total reflection at its interface or the like, and accordingly, the efficiency of extraction of light into the air with respect to actual light emission is as low as about 10 to 20%. Thus, it is difficult to enhance the efficiency.

On the other hand, studies on electroluminescence elements using organic materials have also received attention for a long time, and various studies thereon have been made. However, the studies have not been developed into full-scale studies for practical use because of the very bad luminous efficiency. However, in 1987, Mr. C. W. Tang of Kodak Co., proposed an organic electroluminescence element having a function separation type lamination structure in which an organic material forming a light emitting layer is separated into two layers of a hole transport layer and a light emitting layer. This revealed that a high light emission luminance of 1000 cd/m² or more was able to be obtained in spite of the low voltage of 10 V or less (see, C. W. Tang, and S. A. Vanslyke, Appl. Phys. Lett., (U.S.), vol. 51, 1987, p. 913).

After that, the organic electroluminescence element has suddenly started to receive attention. Even currently, studies on the organic luminescence elements having the same function separation type lamination structure have been increasingly made. In particular, an increase in efficiency/an increase in lifer which are indispensable for putting the organic electroluminescence elements into practical use, have been sufficiently studied. In recent years, a display or the like using an organic electroluminescence element has been realized.

FIG. 12 is a cross sectional view showing a structure of a conventional organic electroluminescence element.

Hereinafter, the structure of a conventional general organic electroluminescence element will be described by reference to FIG. 12.

As shown in FIG. 12 an organic electroluminescence element 11 includes an anode 13 made of a transparent conductive film of ITO or the like formed on, for example, a glass substrate 12 with a sputtering method, a resistance heating evaporation method, or the like, a hole transport layer 14 made of N,N′-diphenyl-N,N′-bis(3-methylphenyl)-1,1′-diphenyl-4,4′-diamine (which is hereinafter abbreviated as TPD) or the like formed on the anode 13 similarly with a resistance heating evaporation method or the like, an organic material layer 15 made of 8-Hydroxyquinoline Aluminum (which is hereinafter abbreviated as Alq₃) or the like on the hole transport layer 14 with a resistance heating evaporation method or the like, and a cathode 17 made of a metal film with a thickness of about 100 to 300 nanometers, formed on the organic material layer 15 with a resistance heating evaporation method or the like.

Incidentally, the hole transport layer 14 and the organic material layer 15 are referred to as merely a light emitting layer 16 as a single unit for convenience. In this case, the light emitting layer 16 may include, other than the hole transport layer 14 and the organic material layer 15, a hole injection layer, an electron injection layer, an electron transport layer, an electron block layer (all not shown), or the like. The following description also follows this example.

18 is a sealing part formed oft for example, glass having a bathtub shape. The sealing part 18 is provided in such a manner as to cover at least the entire surface of the organic electroluminescence element 11, and the outer peripheral portion is bonded to the glass substrate 12 and the like by the use of an adhesive. As described later, the organic electroluminescence element 11 in which the light emitting layer 16 is formed of a low molecular weight organic material layer 15 does not like high temperatures. Therefore, generally, as the adhesive, for example, a photocurable resin which cures upon irradiation with an ultraviolet ray is often used.

When a dc voltage or a dc current is applied via an electric circuit not shown with the anode 13 of the organic electroluminescence element 11 having the foregoing configuration as a positive pole, and with the cathode 17 thereof as a negative pole, holes are injected into the organic material layer 15 via the hole transport layer 14 from the anode 13, and electrons are injected into the organic material layer 15 from the cathode 17. As a result, in the organic material layer 15 forming the light emitting layer 16 interposed between the anode 13 and the cathode 17, recombination of holes and electrons occurs. Upon the transition from the excited state to the ground state of the accordingly resulting exciters, a light emission phenomenon occurs (such a part which is interposed at least between the anode 13 and the cathode 17, and substantially contributes to the light emission is hereinafter referred to as a “light emitting part”).

Thus, in such an organic electroluminescence element 11, the light emitted from the phosphor in the organic material layer 15 is emitted in all directions about the phosphor as the center. Then, the light is emitted from the direction of light extraction (in the direction of the glass substrate 12) into the air via the hole transport layer 14, the anode 13, and the glass substrate 12. Alternatively once, the light goes toward the opposite direction from the direction of light extraction, and it is reflected at the cathode 14, and emitted into the air via the light emitting layer 16, the anode 13, and the glass substrate 12. As described above, the organic electroluminescence elements 11 each have a very simple structure, and can be mass produced. Thus, it has received attention as a technology whereby reduction of the cost and an increase in area of a monitor apparatus such as a display.

On the other hand, however, it is known as one of the problems possessed by the organic electroluminescence element 11 that the light emission region shrinks with time or a dark spot is formed in the light emission region when affected by the moisture. In order to prevent shrinkage or the occurrence or expansion of the dark spot, the organic electroluminescence element 11 is required to be kept in a low humidity state. Thus, the following methods are employed: as described above, the organic electroluminescence element 11 is sealed by the sealing part 18 of glass or the like, and the internal space of the sealing region is rendered into a vacuum state, or an inert gas is filled therein; and the like. Further, in order to still further enhance the effect of sealing, a desiccating agent may be provided in the bathtub-like space.

Incidentally, in recent years, for example, there have also been made research and development for using a so-called gas barrier laminated material having a lamination structure of an organic substance layer made of a resin and an inorganic substance layer made of a metal oxide or the like as the sealing part 18 of the organic electroluminescence element 11 For an example of such a gas barrier laminated material, the manufacturing method disclosed in JP-A-2004-181793 is known. In JP-A-2004-181793, there is the following description, “(first part omitted) many studies have been made on the implementation of a single layer of an inorganic film or an organic film, or a lamination of organic film/inorganic film gas barrier layers; however, it has not been possible to allow the satisfactory gas barrier property to be expressed at all”. In view of this, the following configuration is achieved. On a substrate such as a film, a metal oxide film, a metal nitride film, or a metal film is provided, an organic layer made of a thermosetting resin is stacked thereon, and further, on the organic layer, a second metal oxide film, metal nitride film, or metal film is provided, resulting in a gas barrier laminated material. In the gas barrier laminated material, immediately after stacking of the organic layer which is an intermediate layer, first curing is carried out at a temperature in the range of 120° C. to 180° C., and after the provision of the second metal oxide film, metal nitride film, or metal film, second heat curing is carried out at a temperature in the range of 180° C. to 240° C. As a result it is possible to acquire the gas barrier performance which has been difficult for a single layer of an inorganic film or an organic film, or a lamination of organic film/inorganic film gas barrier layer, or the like to express.

Whereas, as another approach on the sealing technology, for example, the method for manufacturing a light emitting apparatus disclosed in JP-A-2001-237066 is known. JP-A-2001-237066 disclose the following. As a sealing adhesive for bonding the glass substrate 12 and the sealing part 18, a resin having thermosetting property (or thermoplasticity) is allowed to contain a light heat converting substance (i.e., a substance which absorbs an infrared ray or a near infrared ray). This is irradiated with a laser light, and thereby the site at which the sealing part should be bonded is locally heated. Thus, sealing can be carried out without damaging the organic electroluminescence element which generally has only a resistance to heat of 100° C. to 120° C.

It is said as follows. For an organic electroluminescence element, the manufacturing process is simple For this reason, applications such as a light emitting apparatus mounting therein an organic electroluminescence element and an exposure apparatus to which an organic electroluminescence element is applied as a light source are advantageous for the reduction of the cost. However, in the manufacturing process, the sealing step includes a plurality of steps of controlling the temperature as described in JP-A-2004-181793. This reduces the productivity, further directly leading to the increase in cost. As for the manufacturing cost, the manufacturing method of JP-A-2001-237066 in which local sealing is carried out by means of a laser light also has a problem in terms of cost because of the massive manufacturing equipment.

In an actual configuration of a light emitting apparatus, for example, on a substrate forming the light emitting apparatus, an organic electroluminescent element, a driving circuit formed of, for example, TFT, a routing wire, and the like are formed and arranged, and a sealing part covers these structures. In the JP-A-2004-181793 and JP-A-2001-237066, the importance thereof is not even suggested. However, the sealing performances such as a so-called gas barrier property largely depend upon the surface conditions of the structure targeted for adhesion. Therefore, it is an important element for sure sealing with which structure the outer periphery of the sealing part is in contact and bonded.

### SUMMARY OF THE INVENTION

It is an object of the invention to provide a light emitting apparatus for which sealing can be carried out with a simple step using a thermosetting resin as a material for a sealing part, and which has ensured a sufficient barrier property against moisture or a gas without damaging an organic electroluminescence element by heat, and further while using a simple sealing step, and a high reliability exposure apparatus including the light emitting apparatus built therein. In addition, it is another object of the invention to provide a high image quality image forming apparatus mounting therein the exposure apparatus.

A light emitting apparatus of the present invention was completed in view of the foregoing problems. It is configured so as to have a substrate, a plurality of light emitting parts formed by the use of a polymer organic electroluminescence material, an electrode covering the light emitting parts, and a sealing part formed of a thermosetting resin covering at least a wider region than the electrode.

In a polymer organic electroluminescence material, long molecule chains are complicatedly entangled. Thus, even when the material is exposed to a high temperature environment, crystallization does not proceed, resulting in much less characteristic deterioration Therefore, even when a sealing part including a thermosetting resin is provided for a plurality of light emitting parts formed by the use of a polymer organic electroluminescence material, the organic electroluminescence element will not be damaged by the heat applied for curing the sealing part.

Whereas, in general, the barrier property against moisture or a gas of a thermosetting resin is superior to that of a UV curable resin. Therefore, sealing thereof can be carried out with a simple step. Even with a simple configuration, it becomes possible to ensure a sufficient barrier property against the moisture or gases in an atmosphere.

Further, by covering a wider region than the electrode covering the organic electroluminescence elements with this sealing part, it becomes possible to further enhance the barrier property against moisture or a gas without causing the sealing part to extend across the electrode and other structures formed under the electrode. Whereas, the electrode covering the organic electroluminescence element is formed of a metal material (i.e., a material with a high barrier property) such as aluminum or silver as described later. Therefore, it can exhibit a very high sealing performance correlatively with the favorable barrier property of the thermosetting resin.

### BRIEF DESCRIPTION OF THE DRAWINGS

FIG. 1 is a cross sectional view showing a structure of an organic electroluminescence element in a light emitting element substrate of Example 1 of the present invention:

FIG. 2 is a cross sectional view showing a configuration of the outer peripheral portion of a sealing part in the light emitting element substrate of Example 1 of the invention;

FIG. 3 is a cross sectional view of the light emitting element substrate of Example 1 of the invention in which the sealing part has been enlarged to the regions of a contact hole with external circuit and external wiring;

FIGS. 4A and 4B is a top view of the light emitting element substrate of Example 1 of the invention, and an enlarged view of the essential part thereof, respectively;

FIG. 5 is a circuit diagram in accordance with the light emitting element substrate of Example 1 of the invention;

FIG. 6 is a view of a configuration of an exposure apparatus mounting therein the light emitting element substrate of Example 1 of the invention;

FUG. 7 is a view of a configuration of an image forming apparatus mounting therein the exposure apparatus applying the light emitting element substrate of Example 1 of the invention;

FIG. 8 is a view of a configuration showing the periphery of development stations in the image forming apparatus of Example 1 of the invention;

FIG. 9 is a cross sectional view showing a configuration of a light emitting element substrate in Example 2 of the invention,

FIG. 10 is a cross sectional view showing a configuration of a light emitting element substrate in Example 3 of the invention;

FIG. 11 is a cross sectional view showing a configuration of a light emitting element substrate in Example 4 of the invention; and

FIG. 12 is a cross sectional view showing a structure of a conventional organic electroluminescence element.

### DESCRIPTION OF THE PREFERRED EMBODIMENTS

A light emitting apparatus of the present invention is configured so as to have a substrate, a plurality of light emitting parts formed by the use of a polymer organic electroluminescence material on the substrate, an electrode covering the light emitting parts, and a sealing part including a thermosetting resin and covering at least a wider region than the electrode. In the polymer organic electroluminescence material, long molecule chains are complicatedly entangled. Thus, even when the material is exposed to a high temperature environment, crystallization does not proceed, resulting in much less characteristic deterioration. Therefore, even when a sealing part including a thermosetting resin is provided for a plurality of light emitting parts including a polymer organic electroluminescence material, the organic electroluminescence element will not be damaged by the heat applied for curing the sealing part. Whereas, in general, the barrier property against moisture or a gas of a thermosetting resin is superior to that of a UV curable resin. Therefore, sealing thereof can be carried out with a simple step. Even with a simple configuration, it becomes possible to ensure a sufficient barrier property against the moisture or gases in an atmosphere. Further, by covering a wider region than the electrode covering the organic electroluminescence element with this sealing part, it becomes possible to further enhance the barrier property against moisture or a gas without causing the sealing part to extend across the electrode and other portions.

Whereas, the invention is configured so as to include a protective part covering at least the entire surface of the electrode formed between the electrode and the sealing part, wherein the outer peripheral portion of the sealing part is configured so as to be bonded to the protective part. The protective part further covers the entire surface of the electrode covering the entire surface of the light emitting parts. Thus, it improves the barrier property against moisture or a gas, and forms an unevenness-free uniform undercoat for the sealing part and improves the adhesion strength at the outer peripheral portion of the sealing part. Therefore, it becomes possible to improve not only the sealing performance but also the reliability against an external force.

Whereas, the invention is configured so as to have, on the substrate, a wiring part for inputting a control signal involved in driving of at least the light emitting parts, wherein the protective part is configured so as to cover the wiring part, and that the sealing part is configured so as to be bonded to the protective part. As a result, it is possible to form the difference in level of the wiring part disposed on the substrate into an unevenness-free uniform state. This can improve the adhesion strength at the outer peripheral portion of the sealing part.

Whereas, the invention is configured so as to have a pixel regulating part for regulating a light emitting region of each of the light emitting parts on the substrate, wherein the pixel regulating part and the protective part include the same material. As a result, the light emitting parts and the electrode are interposed between the pixel regulating part and the protective part including the same material from above and below, respectively Therefore, the structure of the junction portion of the pixel regulating part and the protective part becomes stable. This enables a further improvement of the sealing performance.

Whereas, the invention is configured such that the protective part and the pixel regulating part include a metal oxide or a metal nitride. As a result, it is possible to obtain a very stable film with a simple method such as a sputtering method. Whereas, the metal oxide or the metal nitride has a very dense structure. Therefore, it can fill the unevenness of the underlying structures without a gap, and can prevent the permeation of moisture or a gas through the gap.

Whereas, the invention is configured so as to have a protective part covering at least a wider region than the electrode formed between the electrode and the sealing part, and such that the sealing part is configured so as to cover a wider region than the protective part. As a result, double sealing is carried out by the protective part and the sealing part. Therefore, it is possible to improve the sealing performance.

Whereas, the invention is configured such that the protective part includes a hygroscopic material. As a result, a trace amount of the moisture which has passed through the sealing part is captured before reaching the light emitting parts by the hygroscopic material. Therefore it is possible to further improve the sealing performance.

Whereas, the invention is configured so as to have a pixel regulating part for regulating a light emitting region of each of the light emitting parts on the substrate, wherein the outer peripheral portion of the sealing part is configured so as to be bonded to the pixel regulating part. The pixel regulating part is formed with a sufficiently large thickness for ensuring the insulating property. The surface of the pixel regulating part exhibits an unevenness-free uniform surface by this thickness Therefore, the adhesion strength at the outer peripheral portion of the sealing part becomes strong. Therefore, it becomes possible to improve not only the sealing performance but also the reliability against an external force, and the like.

Whereas, the invention is configured such that the sealing part includes an epoxy type resin with a glass transition temperature of 140° C. to 180° C. In general, the hardness of the resin after curing increases with an increase in glass transition temperature of the thermosetting resin. However, the adhesion strength is reduced, so that peeling from a substrate is caused by an external or internal stress. Conversely, for a resin with a low glass transition temperature, the adhesion strength inside the resin is reduced, resulting in reduction of airtightness. By setting the glass transition temperature of the sealing part within the foregoing range taking these into consideration, it becomes possible to implement both the adhesion and the airtightness.

Whereas, the invention is configured such that the sealing part is configured so as to contain an inorganic filler having a cleavage property Cleavage represents the following phenomenon: a crystal splits or falls off in a prescribed direction with ease, so that the smooth surface (cleavage plane) is exposed. By this, the entering path of moisture, a gas, or the like passing through the inside of the resin constituting the sealing part becomes very long. This enables a large improvement of the sealing performance.

Whereas, the invention is configured so as to have a driving circuit including a TFT for driving the light emitting parts provided on the substrate, wherein the driving circuit is configured so as to be covered with the sealing part. When cracks occur from an external stress or the like in the driving circuit, the light emitting apparatus suffers a fatal damage of being undrivable. However, by covering the driving circuit part with the sealing part, the driving circuit is protected from an external stress or the like. This enables the improvement of the reliability of the light emitting apparatus.

Whereas, the invention is configured such that the sealing part is configured so as to contain an inorganic porous material (zeolite) having a water absorbing property. As a result, the moisture, gas, or the like passing through the inside of the resin constituting the sealing part is adsorbed on the surface of the inorganic porous material before reaching the light emitting part. This enables a large improvement of the sealing performance.

Whereas, the invention is configured such that the sealing part is configured so as to contain an inorganic porous material having a water absorbing property filled in an amount equal to or more than the amount of a filled inorganic filler having a cleavage property. As a result, the entering path of moisture, a gas, or the like passing through the inside of the resin constituting the sealing part becomes very long. Therefore, the moisture, gas, or the like is adsorbed on the surface of the inorganic porous material before reaching the light emitting part. This enables a large improvement of the sealing performance.

Whereas, the invention is configured such that the sealing part is configured to have a thickness of 50 micrometers or more. The protective part includes a material having a dense structure such as silicon oxide which is a metal oxide, or silicon nitride which is a metal nitride. Therefore, it is possible to configure the protective part thinly. This can shorten the cycle time in the manufacturing process of the protective part. As a result, in such a case that the light emitting apparatus is applied to an exposure apparatus to be mounted in an image forming apparatus for private use, it becomes possible to ensure sufficient sealing performance.

An exposure apparatus of the invention is configured so as to mount therein the light emitting apparatus, wherein the plurality of the light emitting parts are configured in a manner capable of being independently turned ON/OFF. The light emitting apparatus of the invention exhibits a sufficient sealing performance with a very simple structure. Therefore, the exposure apparatus mounting this therein is high in reliability over a long period, and further, it becomes possible to reduce the size, and reduce the cost of the exposure apparatus.

Whereas, the invention is configured such that the light emitting parts are driven by an active matrix circuit provided on the substrate. The electrode (cathode described later) in the active matrix circuit is not required to be formed in stripes as distinct from a passive matrix circuit. Thus, a large number of gaps are not caused between the electrode and the sealing part. Therefore, it becomes possible to improve the sealing performance.

Whereas, a method for manufacturing a light emitting apparatus of the invention includes a step of forming a plurality of light emitting parts by the use of a polymer organic electroluminescence material on a substrate; a step of forming an electrode covering the light emitting parts; and a sealing step of sealing at least a wider region than the electrode with a sealing part including a thermosetting resin. In a polymer organic electroluminescence material, long molecule chains are complicatedly entangled. Thus, even when the material is exposed to a high temperature environment, crystallization does not proceed, resulting in much less characteristic deterioration. Therefore, even when a sealing part including a thermosetting resin is provided for a plurality of light emitting parts made of a polymer organic electroluminescence material, the organic electroluminescence element will not be damaged by the heat applied for curing the sealing part. Whereas, in general, the barrier property against moisture or a gas of a thermosetting resin is superior to that of a UV curable resin. Therefore, sealing thereof can be carried out with a simple step. Even with a simple configuration, it becomes possible to ensure a sufficient barrier property against the moisture or gases in an atmosphere. Further, by covering a wider region than the electrode covering the organic electroluminescence elements with this sealing part, it becomes possible to further enhance the barrier property against moisture or a gas without causing the sealing part to extend across the electrode and other portions.

Whereas, the invention is configured to include a step of, after coating a polymer organic electroluminescence material on the substrate, removing at least the organic electroluminescence material at a position corresponding to the outer peripheral portion of the sealing part. As a result, it becomes possible to prevent external moisture, gas, or the like from entering through the layer including an organic electroluminescence material.

Whereas, the invention is configured to include a step of, after coating a polymer organic electroluminescence material on the substrate, carrying out a heat treatment, wherein the temperature of the heat treatment (baking temperature) is set higher than the temperature for curing the thermosetting resin later. As a result, the organic solvent such as toluene or xylene, containing the polymer organic electroluminescence material dissolved therein is sufficiently evaporated. This enables the stabilization of the performances of the organic electroluminescence elements which are light emitting parts.

Whereas, the invention is configured such that in the sealing step, at least two stages of curing temperatures are set, and the curing temperatures are set such that the latter curing temperature is higher. As a result, it becomes possible to carry out curing of the sealing part with reliability. Further, both of the temperatures for curing the sealing part are set lower than the baking temperature. Thus, the temperature conditions required for processing is eased as the manufacturing process proceeds to a later stage. This can minimize the factors deteriorating the yield such as the occurrence of cracks in the light emitting part due to the thermal expansion of the structure.

Whereas, an image forming apparatus to which the invention is applied includes a photoreceptor on which an electrostatic latent image is formed by the exposure apparatus, and a development means for developing the electrostatic latent image formed on the photoreceptor into an image. The exposure apparatus of the invention has features of high reliability, small size, and low cost. Therefore, the image forming apparatus mounting this therein can hold high image quality for a long period, and the image forming apparatus can be reduced in size and cost.

### EXAMPLES

Below, a light emitting apparatus in accordance with the invention will be described in details. However, in all the following examples, a light emitting element substrate 70 having various structures formed thereon corresponds to the light emitting apparatus in accordance with the invention.

### Example 1

Below, Example 1 of the invention will be described by reference to the drawings.

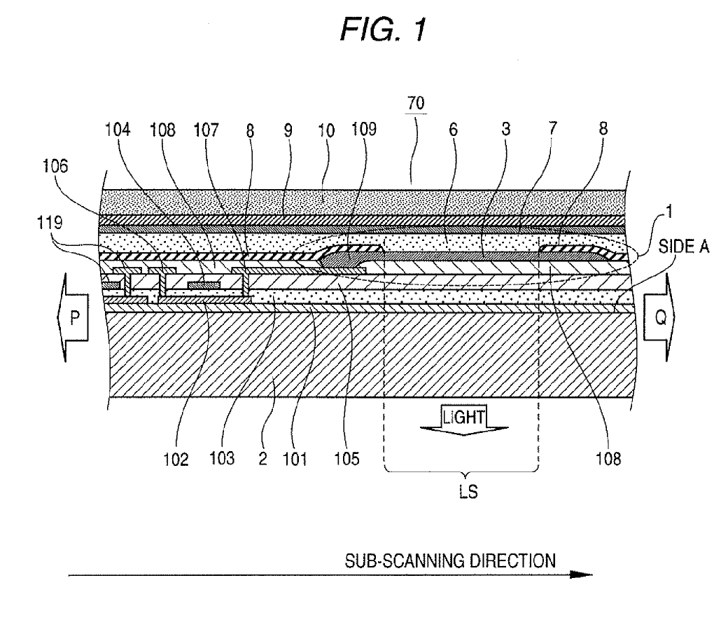

FIG. 1 is a cross sectional view showing a structure of an organic electroluminescence element 1 in a light emitting element substrate of Example 1 of the invention. Below, the structure of the organic electroluminescence element 1 in Example 1 will be described in details by reference to FIG. 1.

In FIG. 1, a reference numeral 1 is an organic electroluminescence element.

<Substrate>

2 is a colorless transparent substrate. As the substrate 2, for example, there can be used inorganic glass including inorganic oxide glass, inorganic fluoride glass, or the like, such as transparent or translucent soda-lime glass, barium-/strontium-containing glass, lead glass, aluminosilicate glass, borosilicate glass, barium borosilicate glass, or quartz glass.

Other materials can also be adopted for the substrate 2. They can be appropriately selected for use from transparent or translucent polymer films or the like using polymer materials such as polyethylene terephthalate, polycarbonate, polymethyl methacrylate, polyether sulfone, polyvinyl fluoride, polypropylene, polyethylene, polyacrylate, amorphous polyolefin, fluorine type resin polysiloxane, and polysilane, or a transparent or translucent chalcogenide glass such as As₂S₃, As₄₀S₁₀, or S₄₀Ge₁₀, materials of metal oxides, nitrides, and the like, such as ZnO, Nb₂O, Ta₂O₅, SiO, Si₃N₄, HfO₂, or TiO₂, or when the light emitted from a light emitting region is extracted not through the substrate, opaque semiconductor materials such as silicon, germanium, silicon carbide, gallium arsenic, or gallium nitride, or the foregoing transparent substrate materials containing a pigment or the like, and metal materials having a surface subjected to an insulating process. A laminated substrate having a plurality of substrate materials stacked one on another can also be used.

Incidentally, in the following description, the structures such as a TFT 102 and the organic electroluminescence element 1 formed on the substrate 2 will be described. However, the substrate 2 and all the structures formed thereon are referred all together as a light emitting element substrate 70 (as described above, this is namely a “light emitting apparatus”).

<TFT>

101 is a base coat layer formed on a side A on the substrate 2, and it is formed by, for example, stacking silicon nitride and silicon oxide. On the base coat layer 101, a TFT 102 formed of polysilicon is formed. In Example 1, as the TFT 102, polysilicon is used, however, amorphous silicon may also be used. The amorphous silicon is low in mobility (about 0.5 cm²/Vs) when it forms a transistor. Thus, it is disadvantageous as compared with high mobility polysilicon (100 to 200 cm²/Vs) in terms of the design rule and the driving frequency. However, it has a cost merit because of the low cost manufacturing process.

103 is a gate insulating layer formed of silicon oxide having a thickness of, for example, about 100 nanometers, and isolate and insulate the TFT 102 and a gate electrode 104 formed of a metal such as molybdenum from one another at a prescribed interval. 105 represents an intermediate layer which is formed by stacking, for example silicon oxide and silicon nitride, and has a thickness of a total of about 350 nanometers. The intermediate layer 105 covers the gate electrode 104, and supports a source electrode 106 and a drain electrode 107 formed of a metal such as Al along the surface. The source electrode 106 and the drain electrode 107 are connected to the TFT 102 via a contact hole provided in the intermediate layer 105 and the gate insulating layer 103. By applying a prescribed electric potential to the gate electrode 104 with a prescribed potential difference applied across the source electrode 106 and the drain electrode 107, the TFT 102 operates as a switching transistor.

108 represents a TFT protective layer formed of silicon nitride or the like. It covers the source electrode 106 entirely, and has an opening, i.e., a contact hole 109 at a part of the drain electrode 107. In general, the TFT protective layer 108 is formed with a thickness of about 300 nanometers. However, when an overcoat layer (not shown) with a resin or the like is not formed thereon, the TFT protective layer 108 may be formed with a slightly larger thickness.

3 represents an anode formed on the TFT protective layer 108. In Example 1, ITO (Indium Tin Oxide) is used. As the anode 3, other than ITO, IZO (zinc-doped indium oxide), ATO (Sb-doped SnO₂), AZO (Al-doped ZnO), ZnO, SnO₂, In₂O₃, or the like can be used. The anode 3 can be formed by a vacuum deposition method, or the like. However, it is desirably formed by a sputtering method or a CVD (Chemical Vapor Deposition) method. The anode 3 is connected to the drain electrode 107 via a contact hole 109.

Incidentally, as shown in FIG. 1, the TFT 102 which is a driving circuit for driving the organic electroluminescence element 1 is entirely covered with a protective part 9 and a sealing part 10. When cracks or the like occur from an external stress or the like in the driving circuit, the light emitting apparatus suffers a fatal damage of being undrivable. However, by covering the driving circuit part with the protective part 9 and the sealing part 10, an external stress ceases to directly act on the TFT 102 which is a driving circuit. This enables the improvement of the reliability of the light emitting apparatus.

<Pixel Regulating Part>

As defined also in the description in Background Art, also in the following description, a part which is interposed at least between the anode and the cathode, and substantially contributes to the light emission is referred to as a “light emitting part”. It will be described as a “light emitting part LS” when it is required to be shown.

8 represents a pixel regulating part for regulating the position, shape, size, and the like of the light emitting part LS contributing to light emission by covering a part of the anode 3. In Example 1, as the pixel regulating part 8, silicon nitride is used, but silicon oxide may be used. The pixel regulating part 8 is formed in the following manner. For example, the metal oxide or the metal nitride is uniformly formed by a deposition method or a sputtering method, followed by patterning, development, and etching, using a photomask. Alternatively, the pixel regulating layer 8 may be formed by a sputtering method via a mask. The thickness of the pixel regulating part 8 formed with the metal oxide or the metal nitride may be properly set at 50 nanometers or more and 2 micrometers or less. When the thickness of the pixel regulating part 8 is less than 50 nanometers, defects occur in the film, resulting in an increase in probability that the portion, which essentially should not emit light, emits light.

Further, as described in details in other examples later, in the configuration in which the outer peripheral portion of the sealing part 10 is bonded to the pixel regulating part 8 for sealing, the barrier property against moisture or a gas may decrease when defects occur in the pixel regulating part 8. Therefore, also from this point of view, a thickness of the pixel regulating part 8 of 50 nanometers or more is desirably ensured.

On the other hand, when the thickness of the pixel regulating part 8 exceeds 2 micrometers, a difference in level between the anode 3 and the pixel regulating part 8 becomes large at the end portion of the pixel regulating part 8 protruding toward the anode 3. As a result, the uniformity of the light emission luminance at a light emitting part LS formed in a wet process described later is deraded.

Incidentally, there are various reasons why the anode 3 is regulated by the pixel regulating part 8 to form the light emitting part LS. For example, the regulation is carried out for determining the position and shape of the light emitting side with precision when an exposure apparatus is assumed. Of course, in the organic electroluminescence element 1, the site at which the opposing anode 3 and cathode 7 overlap each other emits light. Therefore, it is also possible to regulate the shape or the like of the light emitting part LS by the positions and shapes of the anode 3 and the cathode 7. However, for example, for an exposure apparatus, in compliance with the application-side request, the light emitting parts LS each have a very small size and arrangement pitch {e.g., 600 dpi (dot per inch), i.e., the light emitting parts LS each have a size of about 35 micrometers in the direction perpendicular to the paper plane (main scanning direction), and these are arranged at a pitch of 42.3 micrometers). Thus, in order to regulate this by only the electrodes such as the anode 3 and the cathode 7, a high precision becomes necessary for alignment in the manufacturing process. Further, individual electrode lines become too thin, and accordingly, a problem of an increase in the resistance value is also caused. Therefore, the following method is generally employed: an electrode having a certain degree of width is manufactured so as to prevent the resistance value from increasing; and further, a part thereof is regulated by the pixel regulating part 8 to regulate the light emitting side.

<Light Emitting Layer>

6 represents a light emitting layer. In Example 1, as the light emitting layer 6, using a polymer organic electroluminescence material described later, and adopting a spin coating method which is one of wet processes of which the steps are simple, and which can be reduced in cost, the light emitting layer 6 is formed by coating.

In general, the polymer organic electroluminescence material represents an organic electroluminescence material formed in a film with a wet process such as a spin coating method. The low molecular weight organic electroluminescence material represents an organic electroluminescence material formed in a film with a dry process such as a vacuum deposition method. To be exact, the one to which a dry process such as a vacuum deposition method cannot be applied is referred to as a polymer organic electroluminescence material. Incidentally, why a vacuum deposition method cannot be applied to a polymer organic electroluminescence material is for the following reason. For the polymer organic electroluminescence material, self molecular motion occurs before vaporization, and the main chain is cut. Namely, this causes reduction of the molecular weight, so that the inherent capability of the material is reduced.

For coating and forming the light emitting layer 6 including a polymer material with a spin coating method, in Example 1, MEH-PPV dissolved in toluene is used as the polymer organic electroluminescence material, and the film thickness is set to be 120 nanometers. The MEH-PPV is common as the polymer organic electroluminescence material, and it is commercially available from Nihon SiberHegner Co. As the polymer organic electroluminescence materials, other than this, styrene type conjugated dendrimer, and the like can be used.

When the light emitting layer 6 is coated by the foregoing spin coating method, the polymer organic electroluminescence material is coated on all the structures formed on the light emitting element substrate 70 prior to the formation of the light emitting layer 6. In such a case, prior to the formation of the cathode 7 with a deposition method described later, for example, a solvent such as toluene or xylene is recoated, and only a prescribed regions are wiped off with manufacturing equipment for recovery thereof with the molten polymer organic electroluminescence material. The wiping step can also be carried out by, for example, a laser ablation method. Whereas, when there is adopted a step capable of coating a polymer organic electroluminescence material onto only a prescribed region as with a flat printing method using an ink jet technology, the foregoing wiping step becomes unnecessary.

In any case, the following is observed. When the sealing part 10 described later is formed with the polymer organic electroluminescence material coated on the entire surface of the light emitting element substrate 70, moisture gradually enters the inside of the polymer organic electroluminescence element 1 (see, FIG. 1) through the coated light emitting layer 6. Therefore, shrinkage of the light emitting part LS (see, FIG. 1), and expansion of each dark spot tend to proceed. The polymer organic electroluminescence material is required to be removed at least at the outer peripheral portion of the sealing part 10.

After the wiping step, the light emitting element substrate 70 is allowed to stand under an environment at about 180° C. for about 1 hour, to sufficiently evaporate the organic solvent such as toluene or xylene containing the polymer organic electroluminescence material dissolved therein (baking step). Below, the temperature in the baking step is referred to as the baking temperature.

Incidentally, the light emitting element 70 in accordance with the invention is characterized by having the substrate 2, a plurality of light emitting parts LS including a polymer organic electroluminescence material formed on the substrate 2, the electrode (cathode 7 described later) covering the light emitting parts LS, and the sealing part (sealing part 10 described later) including a thermosetting resin and covering the wider region than the electrode. It is a large point that the polymer organic electroluminescence material is used as the material for the light emitting layer 6 forming the light emitting parts LS. Below, the characteristics of the polymer organic electroluminescence material will be described in details through comparison with a conventional low molecular weight electroluminescence material.

Out of the light emitting materials forming the organic electroluminescence element, low molecular weight organic electroluminescence materials often used conventionally are each generally formed in an amorphous film by deposition of the organic compound group with vacuum deposition. Therefore, it is known that they are weak to a high temperature environment. The heat resistance temperature is assumed to be one hundred and several tens degrees centigrade at most. This is due to the following fact: crystallization of the low molecular weight organic compound proceeds when the film is exposed to a high temperature environment, so that the characteristics as the light emitting material are deteriorated. In contrast, the polymer organic electroluminescence material is formed in a thin film by complicated entanglement of the long molecule chains. Thus, no definite crystallization temperature is present, and only an index which should be referred to as a softening starting temperature of a glass transition point is present. Further, for a large number of polymer organic electroluminescence materials, even the definite glass transition point is not observed in some cases. In other words, for the polymer organic electroluminescence material, molecules cannot move freely to crystallize due to the configuration in which molecules are entangled. Such a feature of the polymer organic electroluminescence material emerges as a large advantage of high heat resistance when the polymer organic electroluminescence material is applied to an organic electroluminescence element. This heat resistance temperature including that of HEM-PPV already described sufficiently exceeds 200° C. The light emitting part LS formed by the polymer organic electroluminescence material having the large feature of high heat resistance is not degraded in light emission characteristics even by sealing using a thermosetting resin described later. Thus, the high barrier property against moisture or a gas of the thermosetting resin can be effectively used.

However, even out of the, low molecular weight organic electroluminescence materials deposited by the use of a dry process such as a vacuum deposition method, oligomers having a large molecular weight, and a relatively high glass transition point, more specifically, PPV oligomer and the like, each have an exceptionally high heat resistance, and a wet process can be applied thereto with ease. Therefore, they can be applied to the light emitting element substrate 70 of the invention as substitutes for the polymer organic electroluminescence materials.

Incidentally, in Example 1, the light emitting layer 6 is formed in a single layer film including MEH-PPV. However, it may also be a laminated film including some materials. For example, in order to confine the electric charges injected into the MEH-PPV layer for improving the recombination efficiency, a layer including materials having an electron blocking function or a hole blocking function is added. This leads to the improvement of the characteristics of the element, and hence is desirable. Specifically, the light emitting layer 6 may be configured in a three layer structure of hole transport layer/electron blocking layer/the foregoing organic light emitting material (all not shown) sequentially from the side of the anode 3, or the light emitting layer 6 may be configured in a two layer structure of electron transport layer/organic light emitting material (both not shown) sequentially from the anode 3. Alternatively, it may also be configured in a two layer structure of hole transport layer/organic light emitting material (both not shown) sequentially from the side of the anode 3, or it may be configured in a seven layer structure as with hole injection layer/hole transport layer/electron blocking layer/organic light emitting layer/hole blocking layer/electron transport layer/electron injection layer (all not shown) sequentially from the side of the anode 3. Thus, the cases where a layer is referred to as a light emitting layer 6 in Example 1 also includes the case where the light emitting layer 6 has a multilayered structure having functional layers such as a hole transport layer, an electron blocking layer, and an electron transport layer. The same applies to other examples described later.

As the hole transport layer included in the light emitting layer 6, the one which has high hole mobility, is transparent, and has good film forming property is preferred. Other than TPD described in Background Art, there are used organic materials, including, porphyrin compounds such as porphine, tetraphenylporphine copper, phthalocyanine, copper phthalocyanine, and titanium phthalocyanine oxide, aromatic tertiary amines such as 1,1-bis{4-(di-p-tolylamino)phenyl}cyclohexane, 4,4′,4″-trimethyltriphenylamine, N,N,N′,N′-tetrakis(p-tolyl)-p-phenylenediamine, 1-(N,N-di-p-tolylamino)naphthalene, 4,4′-bis(di methylamino)-2-2′-dimethyltriphenylmethane, N,N,N′-N′-tetraphenyl-4,4′-diaminobiphenyl, N,N′-diphenyl-N,N′-di-m-tolyl-4,4′-diaminobiphenyl, and N-phenylcarbazole, stilbene compounds such as 4-di-p-tolylaminostilbene, and 4-(di-p-tolylamino)-4′-[4-(di-p-tolylamino)styryl]stilbene, triazole derivatives, oxadiazole derivatives, imidazole derivatives, polyarylalkane derivatives pyrazoline derivatives, pyrazolone derivatives, phenylenediamine derivatives, anilamine derivatives, amino-substituted chalcone derivatives, oxazole derivatives, styrylanthracene derivatives, fluorenone derivatives, hydrazone derivatives, silazane derivatives, polysilane type-aniline type copolymers, polymeric oligomers, styrylamine compounds, aromatic dimethylidyne type compounds, and polythiophene derivatives such as poly-3,4-ethylenedioxythiophene (PEDOT), and tetradihexylfluorenyl biphenyl (TFB), and poly-3-methylthiophene (PMeT). Alternatively, there is also used a polymer dispersion type hole transport layer in which in a polymer such as polycarbonate, a low molecular weight organic material for a hole transport layer is dispersed. Further, inorganic oxides such as MoO₃, V₂O₅, WO₃, TiO₂, SiO, and MgO may also be used. Whereas, these hole transport materials may also be used as electron transport materials.

As the electron transport layer in the foregoing light emitting layer 6, there is used a polymer material including an oxadiazole derivative such as 1,3-bis(4-tert-butylphenyl-1,3,4-oxadiazolyl)phenylene (OXD-7), an anthraquinodimethane derivative, a diphenylquinone derivative, or a sirol derivative, or the like, or bis(2-methyl-8-quinolinolate)-(para-phenylphenolate) Al(BAl_{q}), bathocuproine (BCP) or the like. Alternatively, these materials capable of forming the electron transport layer can also be used as hole blocking materials.

Up to this point, the light emitting layer 6 in Example 1 was described in details. However, the polymer organic electroluminescence materials forming the light emitting layer 6 are not limited to the MEH-PPV described above. The ones having a fluorescence or phosphorescence characteristic in the visible region, and good film forming property can be selected. For example, a polymer light emitting material such as polyparaphenylene vinylene (PPV) or polyfluorene can be used. Further, currently, polymer type organic electroluminescence materials having various characteristics and light emission colors are proposed. A material can be appropriately selected from these to form the light emitting layer 6.

<Cathode>

7 represents a cathode formed by, for example, subjecting a metal material such as Al to a vacuum deposition method. As the cathode 7 of the organic electroluminescence element 1, there is used a metal or an alloy having a low work function, for example, a metal such as Al, In, Mg, or Ag, a Mg alloy such as Mg—Ag alloy or a Mg—In alloy, or an Al alloy such as an Al—Li alloy, an Al—Sr alloy, or an Al—Ba alloy. Alternatively, there can also be used a metal such as Ba, Ca, Mg, Li, or Cs, or a metal lamination structure including a first electrode layer in contact with an organic matter layer including a fluoride or an oxide of the metals, such as LiF or CaO, and a second electrode layer including a metal material such as Al, Ag, or In, formed thereon.

The cathode 7 is required to cover at least the entire surface of the light emitting part LS from the necessity of supplying electric charges to the light emitting part LS. However, the cathode 7 formed from a metal is allowed to cover the entire surface of the light emitting part LS, and as a result, it can be allowed to also have the sealing function of preventing external moisture from entering.

In Example 1, the organic electroluminescence element is covered with the cathode 7 formed from a metal having a high barrier property against a gas or moisture. Further, the whole of the cathode 7 is covered as described later. Thus, a light emitting apparatus is formed with a thermosetting resin having a high barrier property.

With the structure and steps described up to this point, the organic electroluminescence element 1 is formed on the substrate 2. The TFTs 102 are formed in a relationship of 1:1 with the individual organic electroluminescence elements 1, and electrically form a so-called active matrix circuit The source electrode 106 is set as a positive pole, and a prescribed electric potential difference is provided between the source electrode 106 and the cathode 7. Further, the gate electrode 104 is controlled at a prescribed electric potential. As a result, holes are injected into the light emitting layer 6 through the source electrode 6, the TFT 102, the drain electrode 107, and the anode 3. On the other hand, electrons are injected from the cathode 7 to the light emitting layer 6. In the light emitting layer 6, recombination of holes and electrons occurs. Upon the transition from the excited state to the ground state of the accordingly resulting exciters, a light emission phenomenon occurs.

Thus, the light emitting apparatus of Example 1 has an active matrix structure, and the cathode 7 is formed over the entire surface of a plurality of the organic electroluminescence elements 1. When a passive matrix structure is adopted, the cathode is required to be formed in stripes. As a result, a level difference due to a large number of cathodes is caused. However, when an active matrix structure is adopted, it does not occur that the level difference between the cathodes adversely affects the sealing performance. This is also one factor for improving the sealing performance.

The light emitted from the light emitting layer 6 passes through the anode 3, the intermediate layer 105, the gate insulating layer 103, the base coat layer 101, and the substrate 2, and is emitted from the opposite side from the side A of the substrate 2, and exposes a photoreceptor not shown.

<Protective Part>

9 represents a protective part formed with a material having a dense structure such as silicon oxide which is a metal oxide, or silicon nitride which is a metal nitride. The protective part 9 is formed so as to cover at least the entire surface of the cathode 7 as described in details later. In Example 1, the protective part 9 is a film-like structure having a thickness of at least 50 nanometers, and it is formed by, for example, a sputtering method. When the light emitting element substrate 70 of Example 1 is applied to an exposure apparatus, the light emitting element substrate 70 is not required to have flexibility. Therefore, basically, the protective part 9 may be properly formed as thick as, for example, about 10 micrometers when time constraints in the manufacturing step permit. By increasing the thickness of the protective layer 9 in this manner, as a corollary, the barrier property against moisture or a gas is remarkably improved. Further, the difference in level due to the underlying structures covered with the protective layer 9, or the like is absorbed with reliability. Resultantly, the surface of the protective part 9 comes in an unevenness-free uniform state. As a result, the adhesion with the sealing part 10 described later becomes very stable, and it is possible to achieve close adhesion between the bonding sides of the protective part 9 and the sealing part 10. Therefore, it becomes possible to effectively prevent moisture from entering from the gap therebetween Whereas, the surface of the protective part 9 is in an unevenness-free uniform state. Therefore, the adhesion strength at the outer peripheral portion of the sealing part 10 becomes very strong, and it becomes possible to improve the reliability to breakage by an external force, or the like. As an alternate to the silicon oxide or silicon nitride, for example, silicon oxynitride may be used.

<Sealing Part>

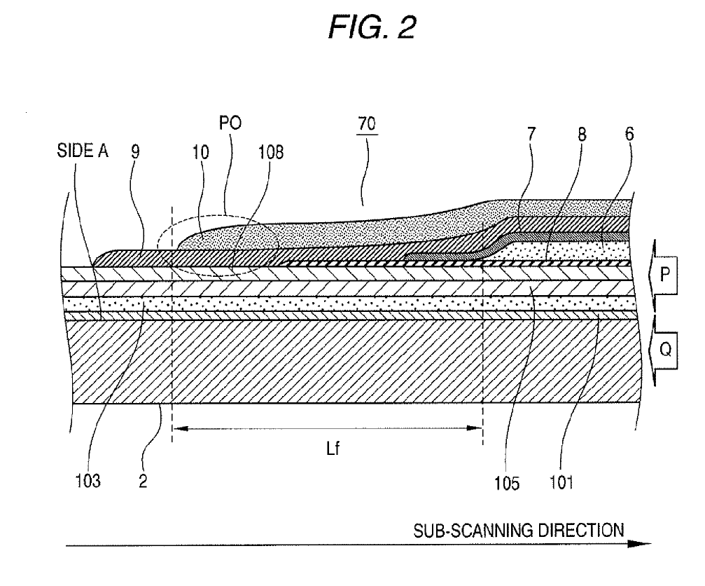

10 represents a sealing part formed of a thermosetting resin. The sealing part 10 entirely covers at least the light emitting part LS which is regulated in terms of size and shape by the pixel relating part 8 as shown As described in details by reference to FIG. 2 later, the sealing part 10 further entirely covers the cathode 4, and in Example 1, the outer peripheral portion is bonded to the protective part 9.

Incidentally, the thermosetting resins are generally epoxy type resins and acrylic resins. However, in Example 1, epoxy type resins are adopted in view of the small thermal shrinkage property and less degassing. For forming the sealing part 10 on the light emitting element substrate 70, a thermosetting resin is coated using a dispenser on the top side of the protective part 9 formed on the light emitting element substrate 70. However, by controlling the coating rate of the dispenser, and the amount of the thermosetting resin to be supplied, it is possible to form the sealing part 10 with a prescribed thickness.

The thickness required for the sealing part 10 will be described below. The light emitting element substrate 70 in Example 1 is intended to be applied to an exposure apparatus mounted to an image forming apparatus for personal use. With a thickness of the sealing part 10 of about 100 micrometers, sufficient sealing performance is exhibited. On the other hand, for example, for the application use with a relatively small possibility of being allowed to stand in a high humidity environment for a long time such as the display use of a monitor apparatus, it is only essential that the thickness of the sealing part 10 is 50 micrometers or more. Whereas, for the application use with a high possibility of being allowed to stand in a relatively high humidity environment as with an exposure apparatus to be applied to a so-called high speed type image forming apparatus, it is only essential that the thickness of the sealing part 10 is about 200 micrometers as a guide.

The method for coating a thermosetting resin is not limited to the dispenser.

Whereas, although the curing conditions vary according to the thermosetting resin used, desirably, a heat treatment is carried out at 100° C. as a first curing temperature for about 1 hour, and then, another heat treatment is further carried out at 150° C. for about 1 hour. In order to relieve the stress due to sudden heating, it is desirable to gradually carry out heating and curing.

In general, when the light emitting layer 6 of the organic electroluminescence element 1 is formed of a low molecular weight material, and the sealing part 10 is cured under an environment at high temperatures such as 100° C. and 150° C., the low molecular material forming the light emitting layer 6 crystallizes, resulting in loss of the light emitting function. Further, once the material crystallizes, the original molecular state will not be reconstructed even when the temperature is reduced. In contrast, when the already described polymer materials are used, the molecular state will not change even under such a high temperature environment, and the light emitting function is held.

In Example 1, as a thermosetting resin, an epoxy resin was used. However, other than this, mention may be made of polycarbonate, polymethyl methacrylate, polyacrylate, methyl phthalate homopolymer, or copolymer, polyethylene terephthalate, polystyrene, diethylene glycol bisallyl carbonate, acrylonitrile/styrene copolymer, poly(-4-methylpentene-1), phenol resin, cyanate resin, maleimide resin, polyimide resin, acrylic resin, or the like. Alternatively, there can be also used the ones obtained by modifying these with polyvinyl butyral, acrylonitrile-butadiene rubber, multifunctional acrylate compounds, and the like, or thermosetting resins resulting from modification with thermoplastic resins such as crosslinked polyethylene resin, crosslinked polyethylene/epoxy resin, and polyphenylene ether/cyanate resin. Further, a plurality of the resins as mentioned above may also be used in combination. Incidentally, even a photocurable resins are usable so long as curing thereof is promoted by heating.

The epoxy type resins for use as the sealing part 10 include two types of photocurable resins and thermosetting resins. To the former, a photoreactive crosslinking initiator has been added. Thus, the curing reaction is initiated by light, and then, as a final treatment, curing is effected at a relatively low temperature, for example, 80° C. In contrast, for the latter thermosetting resins, the curing reaction is also initiated by heat, and all curing processes are effected by heat. Therefore, the crosslinking density controlling the adhesion is higher for the thermosetting resins than for the photocurable resins. This crosslinking density has a close relation with the barrier property against moisture or a gas, and the larger the crosslinking density is, the more the barrier property is also improved.

Further, the hardness of the resin after curing increases with an increase in glass transition temperature of the thermosetting resin. Therefore, the adhesion strength is reduced, so that peeling from a substrate is caused by an external or internal stress. For this reason, the sealing performance is not necessarily enhanced with an increase in glass transition temperature of the resin. Conversely, for a resin with a low glass transition temperature, the adhesion strength inside the resin is reduced, resulting in reduction of airtightness. Taking these into consideration, it is desirable that a resin having a glass transition temperature in the range of 140° C. to 180° C. is selected.

Further, in order to improve the moisture permeability of the resin, a filler of an inorganic matter may be added to the resin itself. Addition of a filler of an inorganic matter can lengthen the entering path of moisture, a gas, or the like passing through the inside of the resin. Further, in order to minimize the damage on the polymer organic electroluminescence by degassing from the resin, the substances such as a solvent and a reaction initiator are more desirably in smaller amounts.

The filler of an inorganic matter is desirably, for example, a plate-like inorganic filler or a flaky inorganic filler. The plate-like inorganic filler or the flaky inorganic filler is an inorganic filler having a cleavage property in most cases. Cleavage represents the following phenomenon: a crystal splits or falls off in a prescribed direction with ease, so that the smooth surface (cleavage plane) is exposed. In other words, resultantly, when a filler has a cleavage property, individual particles of the filler become plate-like or flaky. Examples of such an inorganic filler may include talc and mica. However, even glass flakes are also acceptable so long as they satisfy only the requirement on the shape, and there is no particular restriction thereon.

Further, the amount of the inorganic filler is also an important factor. By setting the content of an inorganic filler including a plate-like inorganic filler or a flaky inorganic filler at 20 percent by weight or more in the thermosetting resin for use in the invention, it is possible to remarkably reduce the moisture permeability of the sealing part 10.

Further, in order to improve the moisture permeability of the resin, an inorganic porous material having micropores in the surface, such as a so-called zeolite may be added to the resin itself, as with the filler of an inorganic matter. By adding the inorganic porous material thereto, the moisture, gas, or the like passing through the inside of the resin is adsorbed in the micropores formed in the surface of the inorganic porous material, and captured before reaching the light emitting part. Further, the removed gas component from the resin is also adsorbed thereby. As a result, it becomes possible to suppress the damage on the polymer organic electroluminescence.

The inorganic porous material is preferably, for example, a natural zeolite, a synthetic zeolite, or silica gel. Alternatively, an activated carbon having a porous surface is also usable. Further, the diameter of the inorganic porous material is desirably 5 micrometers or less. When it is 10 micrometers or more, a short circuit of the polymer organic electroluminescence is caused thereby.

Further, the amount of the inorganic porous material to be added is also an important factor as with the inorganic filler including a plate-like inorganic filler or a flaky inorganic filler. By setting the content of the inorganic porous material to be equal to, or more than that of the inorganic filler including a plate-like inorganic filler or a flaky inorganic filler in the thermosetting resin for use in the invention, it is possible to remarkably reduce the moisture permeability of the sealing part 10.

Incidentally, as described in <Light emitting layer>, the polymer organic electroluminescence material has a far higher heat resistance temperature as compared with the low molecular weight organic electroluminescence material. Therefore, in the case where the light emitting layer 6 is formed of a polymer organic electroluminescence material, the light emission characteristics of the organic electroluminescence element 1 is not degraded even when a thermosetting resin far superior in the barrier property against moisture or a gas to a photocurable resin is adopted as the sealing part 10. By sealing the organic electroluminescence element 1 formed of a highly heat-resistant polymer organic electroluminescence material using a thermosetting resin in this manner, it is possible to obtain a high sealing performance even though the light emitting element substrate 70 of the invention has a simple structure, and can be manufactured with a simple step.

For the thermosetting resin forming the sealing part 10, the final curing temperature is set at 150° C. However, as described in <Light emitting layer>, the baking temperature on the light emitting layer 6 formed of a polymer organic electroluminescence material is 180° C. Namely, in Example 1, for the formation of the light emitting parts LS, a prescribed heat treatment (baking step) is carried out. In addition, the temperature for curing the thermosetting resin is controlled to a lower temperature than the prescribed temperature of the heat treatment.

Thus, the temperature conditions required for processing is eased as the manufacturing process proceeds to a later stage. This can minimize the factors deteriorating the yield such as the occurrence of cracks in the light emitting layer 6 due to the thermal expansion of the structure.

<Sealing Part Outer Peripheral Portion>

FIG. 2 is a cross sectional view showing a configuration of the outer peripheral portion of the sealing part 10 in the light emitting element substrate 70 of Example 1 of the invention.

Below, by reference to FIG. 2, the configuration of the outer peripheral portion of the sealing part 10 will be described in details.

In FIG. 2, an arrow P indicates that the structures forming the light emitting element substrate 70 (i.e., the substrate 2, the base coat layer 101, the gate insulating layer 103, the intermediate layer 105, the TFT protective layer 108, the pixel regulating part 8, the light emitting layer 6, the cathode 7, the protective part 9, and the sealing part 10) are formed continuously from the arrow P of FIG. 1. The same also holds for an arrow Q. However, FIGS. 1 and 2 are not directly connected with each other at the positions of the arrows P and Q, but connected through some space not shown. Whereas, the arrow Q indicates that the structure obtained by inverting FIG. 2 along the lateral direction of the paper plane is formed continuously from the position of the arrow Q of FIG. 1.

As shown in FIG. 2, in Example 1, a protective part 9 which covers at least the entire surface of the electrode (cathode 7) is formed between the electrode (cathode 7) and the sealing part 10. The outer peripheral portion of the sealing part 10 is configured so as to be in contact with the protective part 9.

After the baking step described in <Light emitting layer>, the cathode 7 is formed in such a manner as to cover at least the entire surface of the light emitting part LS (see, FIG. 1) by a vacuum deposition method. The region where the cathode 7 is to be formed can be adjusted with a relative high degree of freedom by a mask in vacuum deposition. In Example 1, after the formation of the cathode 7, the protective part 9 is formed in such a manner as to cover at least the entire surface of the cathode 7 and the pixel regulating part 8. As already described, in Example 1, the pixel regulating part 8 is formed with silicon oxide or silicon nitride. At this step, the protective part 9 is desirably formed of the same material as the material forming the pixel regulating part 8. Namely, desirably, when the pixel regulating part 8 is silicon oxide which is a metal oxide, the protective part 8 is also similarly silicon oxide. This makes stronger the bond at the contact portion between the pixel regulating part 8 and the protective part 9. As a result, it becomes possible to enhance the effect of shielding the light emitting part 6 and the cathode 7 interposed therebetween from the outside.

After the formation of the protective part 9, the sealing part 1 a is formed with the step described in <Sealing part>. At this step, the outer peripheral portion PO of the sealing part 10 is bonded with the protective part 9. As already described in <Sealing part>, the protective part 9 is formed of a very dense material such as silicon oxide, and can be formed sufficiently thickly. Therefore, the surface of the protective part 9 is not affected by the unevenness of the underlying structures, and hence has a very high smoothness. As a result, the sealing part 10 formed on the protective part 9 is bonded to the protective part 9 with stability.

Incidentally, even when the protective part 9 and the sealing part 10 are bonded with each other strongly in this manner to render the internal organic electroluminescence element 1 into a closed state, a very trace amount of moisture may enter into the organic electroluminescence element 1. In order to minimize this, and ensure the reliability over a long time of the light emitting element substrate 70, it becomes necessary to ensure the maximum distance Lf between the end portion of the light emitting layer 6 subjected to wiping (see, the description of <Light emitting layer> for the wiping step) and the outermost periphery of the sealing part 10 (sealing margin). The sealing margin Lf is required to be at least 0.5 millimeter or more. When it is 2 millimeters or more, sufficient sealing performance can be ensured.

In general, in the structure in accordance with the TFT 102 forming the light emitting element substrate 70 (see, FIG. 1), an interface for inputting a control signal for driving the TFT 102 is formed in the periphery of the TFT protective layer 108. Specifically, in the periphery of the TFT protective layer 108, a contact hole (not shown) for contact with an external circuit is formed. However, unevenness occurs on the contact hole and the external wiring (not shown) connected to the contact hole. Therefore, even when the region of the sealing part 10 is expanded merely for ensuring the sealing margin Lf, the barrier property against moisture or a gas may be conversely impaired by the underlying unevenness when the sealing part 10 covers the contact portion.

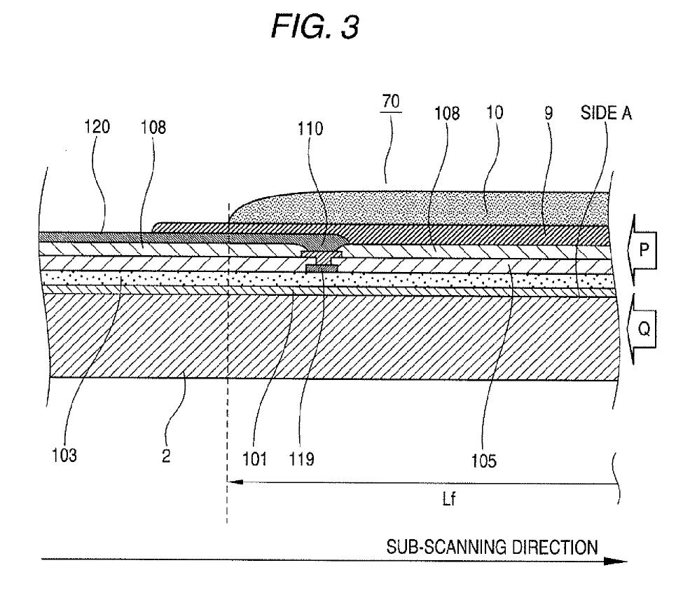

FIG. 3 is a cross sectional view of the light emitting element substrate 70 of Example 1 of the invention in which the sealing part 70 has been enlarged to the regions of a contact hole with external wiring and external wiring.

Below, a description will be given to the configuration in which the sealing part 10 has been enlarged to the regions of a contact hole with external wiring and external wiring by reference to FIG. 3. Incidentally, in FIG. 3, the light emitting layer 6 and the cathode 7 shown in FIG. 2 are not shown. This is for the following reason: the sealing margin Lf indicative of the distance between the end portion of the light emitting layer 6 and the outermost periphery of the sealing part 10 is sufficiently large, and the light emitting layer 6 and the cathode 7 are not present in the region shown in FIG. 3.

In FIG. 3, 119 represents a wiring pattern provided on the gate insulating layer 103. 110 represents a contact hole provided as an opening in the TFT protective layer 108 for establishing a connection with an external circuit (not shown). 120 represents an external wiring connected to the contact hole 110 and connecting the wiring pattern 119 and an external wiring (not shown). In FIG. 3, only one contact hole 110 and only one external wiring are shown. However, in an actual light emitting element substrate 70, a plurality of respective ones are provided in the direction perpendicular to the paper plane. Therefore, on the surface of the TFT protective layer 108, unevenness due to the presence or absence of the external wiring 120 occurs.

In Example 1, the light emitting element substrate 70 has a wiring part (external wiring 120) for inputting a control signal in accordance with driving of at least the light emitting part LS (see, FIG. 1), and the protective part 9 is configured so as to cover the external wiring 120, and the sealing part 10 is configured so as to be bonded to the protective part 9.

The external wiring 120 formed on the TFT protective layer 108 has a multilayered structure in which ITO is used as the base, and a metal layer of, for example, molybdenum is provided thereon in order to reduce the wiring resistance. It can be formed by, for example, a sputtering method. The thickness of the external wiring thus formed is about 150 to 200 nanometers. As already described in <Sealing part>, the protective part 9 can be formed with a sufficient thickness of, for example, several tens micrometers. Therefore, the unevenness formed by the external wiring 120 having a thickness of about 200 nanometers at most is almost completely filled by the protective part 9. As a result, the region where the contact hole 110 and the external wiring 120 are present comes to have a uniform side without unevenness by the protective part 9. Whereas, for the formation of the protective part 9, a dry process such as a sputtering method is adopted. Therefore, the metal oxide or the metal nitride forming the protective part 9 fills the unevenness due to the external wiring 120 very densely. Thus, a gap inhibiting the barrier property against moisture or a gas is not formed therebetween.

In Example 1, at least the outer peripheral portion of the sealing part 10 is bonded on the protective part 9 thus formed. Therefore, the sealing part 10 is bonded with the protective part 9 very stably.

Incidentally, when the protective part 9 is formed so as not to reach the region where the external wiring 120 is formed as shown in FIG. 2, as the protective part 9, a metal may be used in place of the metal oxide or the metal nitride. With such a configuration, the TFT 102 (see, FIG. 1) and the whole region associated with wiring thereof are covered with a metal (and the electric potential is the same as that of the cathode 7 and may be GND). As a result, it becomes possible to cut off an external noise, and to reduce the malfunctions of the TFT 102 (see, FIG. 1). However, in this case, the wiring pattern 119 and the protective part 9 are present in the very vicinity of each other. Therefore, the operating speed of the TFT 102 (see, FIG. 1) may restricted by the capacitance. For this problem, an increase in thickness of the intermediate layer 105 and the TFT protective layer 108 can enable the compatibility between the noise resistance and the delay due to the capacitance.

On the other hand, when the protective part 9 is formed so as to extend to the region where the external wiring 120 is formed as shown in FIG. 3, the protective part 9 is required to have an insulating property. Therefore, as the material for forming the protective part 9, a metal cannot be used, but the already described metal oxide or metal nitride is used.

<Overall Configuration of the Light Emitting Element Substrate>

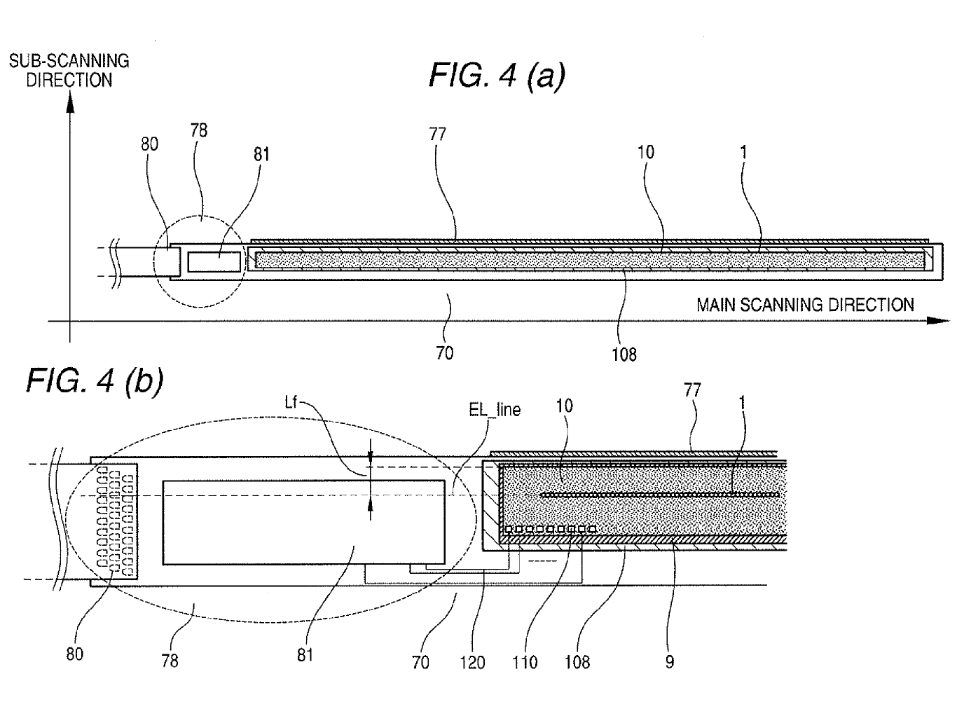

FIG. 4A is a top view of the light emitting element substrate 70 of Example 1 of the invention. FIG. 4B is an enlarged view of the essential part thereof. Below, by reference to FIGS. 4A and 4B, the configuration of the light emitting element substrate 70 in Example 1 will be described in details.

In FIGS. 4A and 4B, the light emitting element substrate 70 is a rectangular substrate having at least long sides and short sides, with a thickness of about 0.7 millimeter, wherein a plurality of organic electroluminescence elements 1 which are light emitting elements are formed in rows along the long side direction (main scanning direction). As already described, the light emitting part (not shown) of the organic electroluminescence element 1 is formed of a polymer organic electroluminescence material. In Example 1, light emitting elements required for at least A4-size (210-millimeter) exposure are arranged along the long side direction of the light emitting element substrate 70. The length along the long side direction of the light emitting element substrate 70 is set to be 250 millimeters inclusive of the arrangement space of a driving control part 78 described later. Whereas, in Example 1, the light emitting element substrate 70 is described as a rectangle for simplification. However, for alignment when the light emitting element substrate 70 is mounted to the housing A 74a of an exposure apparatus described later, or for other purposes, a modification may be made such that notches are provided in parts of the light emitting element substrate 70.

78 represents a driving control part for receiving a control signal (signal for droving the organic electroluminescence element 1) supplied externally of the light emitting element substrate 70, and controlling driving of the organic electroluminescence element 1 based on the control signal. As described later, it includes an interface means (FPC80) for receiving a control signal externally of the light emitting element substrate 70, and an IC chip (source driver 81) for controlling the driving of the light emitting element based on the control signal received via the interface means.

80 represents a FPC (flexible printed circuit) as an interface means for connecting the connector A 73a of a relay substrate 72 and the light emitting element substrate 70. It is directly connected to a circuit pattern not shown provided on the light emitting element substrate 70 not via a connector or the like. As already described, image data, light amount correction data, control signals such as clock signals and line synchronization signals, a driving power for the control circuit, and a driving power for the organic electroluminescence element 1 which is a light emitting element are supplied to the light emitting element substrate 70 once via the relay substrate 72 shown in FIG. 2, and then via the FPC 80.

In Example 1, as light sources of an exposure apparatus described later, 5120 organic electroluminescence elements 1 as light sources of an exposure apparatus described later are formed in rows at a resolution of 600 dpi along the longitudinal direction (main scanning direction) of the light emitting element substrate 70. Individual organic electroluminescence elements 1 are each independently controlled in ON/OFF by a TFT circuit described later.

81 represents a source driver supplied as an IC chip for controlling the driving of the organic electroluminescence element 1. It is flip-chip mounted on the light emitting element substrate 70. In consideration of carrying out surface mounting on the glass side, as the source driver 81, a bare chip product is adopted. To the source driver 81, power, control-related signals such as clock signals and line synchronization signals, and light amount correction data (e.g., 8-bit multilevel data) are supplied externally of an exposure apparatus via the FPC 80. The source driver 81 is as described in details later, a driving parameter setting means for the organic electroluminescence elements 1. More specifically, it is for setting the driving current values of individual organic electroluminescence elements 1 based on the light amount correction data delivered via the FPC80.

In the light emitting element substrate 70, the junction part of the FPC 80 and the source driver 81 are connected with other, for example, via a circuit pattern of ITO having a metal formed on the surface (not shown). Thus, to the source driver 81 serving as a driving parameter setting means, light amount correction data and control signals such as clock signals and line synchronization signals are inputted via the FPC 81. In this manner, the FPC 80 as an interface means and the source driver 81 as a driving parameter setting means form the driving control part 78.

108 represents the already described TFT protective layer. Under the surface of the TFT protective layer 108, a TFT (Thin Film Transistor) circuit not shown is formed. The TFT circuit includes a gate controller for controlling the timing of ON/OFF of the light emitting element such as a shift register or a data latch part, and a driving circuit for supplying a driving current to individual organic electroluminescence elements 1 (which is hereinafter referred to as a pixel circuit). The pixel circuits are provided one for each organic electroluminescence element 1, and arranged in parallel with the light emitting element rows formed by the organic electroluminescence elements 1. As described in details later, a driving current value for driving each organic electroluminescence element 1 is set at the pixel circuit by the source driver 81 serving as a driving parameter setting means.

To the TFT circuit (not shown), power, control signals such as clock signals and line synchronization signals, and image data (1-bit binary data) are supplied externally of an exposure apparatus (not shown) via the FPC 80. The TFT circuit controls the ON/OFF timing of an individual light emitting element based on the power and signals.

As already described, 9 represents a protective part formed on the TFT protective layer 108, and the sealing part 10 is provided on the protective part 9. In the TFT protective layer 108, a contact hole 110 is formed. To the contact hole 110, the external wiring 120 is connected. In FIGS. 4A and 4B, for ease of description, the organic electroluminescence element 1, the contact hole 110, and the external wiring 120 are drawn in a visually observable manner. However, these are covered with the protective part 9 and the sealing part 10, and hence, in actuality, these cannot be visually observed. Incidentally, FIGS. 4A and 4B show the case of a configuration in which the protective part 9 covers the whole of the contact holes 110 and a part of the external wiring 120, and which corresponds to the configuration described with reference to FIG. 3.

In Example 1, as shown in FIGS. 4A and 4B, the contact hole 110 is provided as an opening in the TFT protective layer 108, and configured so as to be connected to the source driver 81 via the external wiring 120 with ITO+metal. However, the following configuration may be adopted. The TFT protective layer 108 is expanded to the arranging region of the source driver 81, an opening of the contact hole 110 is provided at the position corresponding to the signal terminal (bump site) of the source driver 81 which is an IC chip (bare chip), and the source driver 81 is directly bonded thereto. With this configuration, it becomes possible to form the external wiring 120 simultaneously in the process of forming the TFT circuit. This can simplify the manufacturing process of the light emitting element substrate 70. Further, similarly, the wiring between the junction part of the FPC 80 and the source driver 81 can also be provided under the TFT protective layer 108.

77 represents a light amount sensor unit including a plurality of light amount sensors formed of amorphous silicon or the like disposed in the main scanning direction along the light emitting element substrate 70. The emission light amount of the individual organic electroluminescence element 1 is measured by the light amount sensor unit 77. An output from the light amount sensor unit 77 is once captured and amplified in a TFT circuit (not shown) through wiring not shown, and subjected to a signal processing such as analogue/digital conversion. Then, it is outputted to the outside of the light emitting element substrate 70 via the FPC 80.

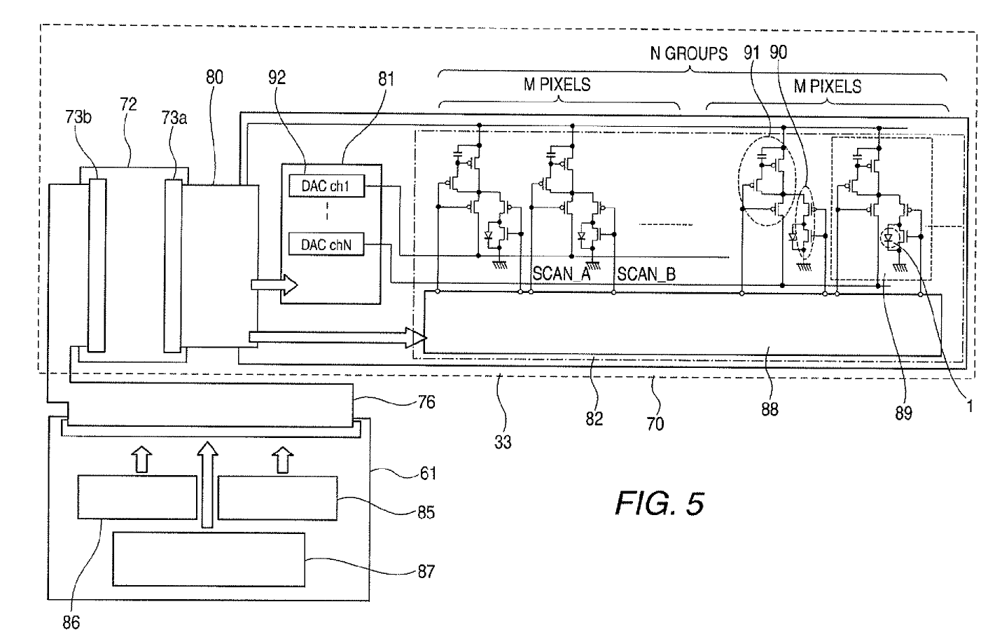

This signal is received/processed at a controller 61 (see, FIG. 5) described later to generate light amount correction data (e.g., 8 bit). Thus, the emission light amounts of all the organic electroluminescence elements 1 are controlled so as to be generally equal one another.

Incidentally, in Example 1, in the light emitting element substrate 70, the FPC 80 serving as an interface means forming the driving control means 78, and the source driver 81 serving as a driving parameter setting means are disposed at a position on the extension (EL_dir) of the light emitting element rows formed with the organic electroluminescence elements 1.

With such an arrangement, at a given position along the long side direction (main scanning direction) of the light emitting element substrate 70, the driving control part 78 is disposed at a position not overlapping the light emitting element rows. Simultaneously, with this configuration, at a given position along the long side direction (main scanning direction) of the light emitting element substrate 70, the driving control part 78 is disposed at a position also not overlapping the TFT circuit (not shown) formed in parallel with the light emitting element rows. Further, for the sealing part 10, a bathtub-like glass plate or the like is not used as in the related art. Only the regions requiring sealing in the light emitting element substrate 70 are subjected to sealing. Therefore, by the synergistic effect with the arrangement of the driving control part 78, it becomes possible to reduce the size of the light emitting element substrate 70, particularly, the size along the sub-scanning direction. In general, when a TFT circuit is formed in a glass substrate or the like, even more than the simplification of the manufacturing process, the number of substrates to be cut from a prescribed sized motherboard most affects the cost. Therefore, by reducing the size of the light emitting element substrate 10, it becomes possible to dramatically reduce the manufacturing cost of the light emitting element substrate 70.

<Lighting Control of Organic Electroluminescence Element and Size of Light Emitting Element Substrate>

FIG. 5 is a circuit diagram in accordance with the light emitting element substrate 70 of Example 1 of the invention. Below, by reference to FIG. 5, lighting control with the TFT circuit and the source driver 81 will be described in more details.

In FIG. 5, 82 represents a TFT circuit formed on the light emitting element substrate 70. 61 represents a controller built in an image forming apparatus. It receives image data from a computer not shown, or the like, and generates printable image data. In addition, it generates light amount correction data based on an output from the light amount sensor unit 77 (see, FIG. 4A) disposed on the light emitting element substrate 70 as described above.

85 represents an image memory storing therein binary image data generated by the controller 61 based on a command transferred from a computer not shown, or the like. 86 represents a light amount correction data memory storing light amount correction data. The light amount correction data memory 86 is a rewritable nonvolatile memory such as an EEPROM. The manufacturing process of an exposure apparatus 33 includes a step of measuring the emission light amounts and the light emission luminance distribution of all the organic electroluminescence elements 1 for individual exposure apparatuses 33, and generating light amount correction data for making substantially equal the light emission amounts of respective organic electroluminescence elements 1 based on these measured results. In the light amount correction data memory 86, the values of the light amount correction data are stored.

The controller 61 can update the light amount correction data to the light amount correction data newly generated based on an output from the light amount sensor unit 77 (see, FIG. 4A).

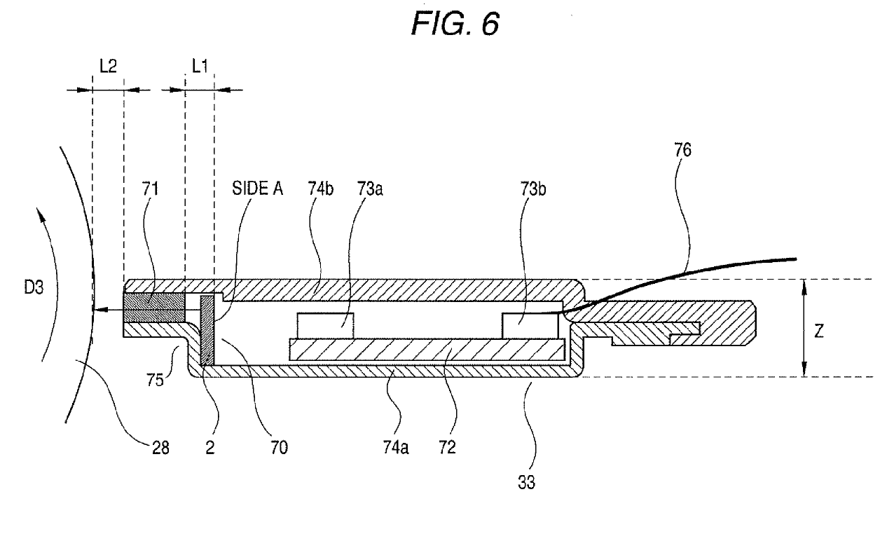

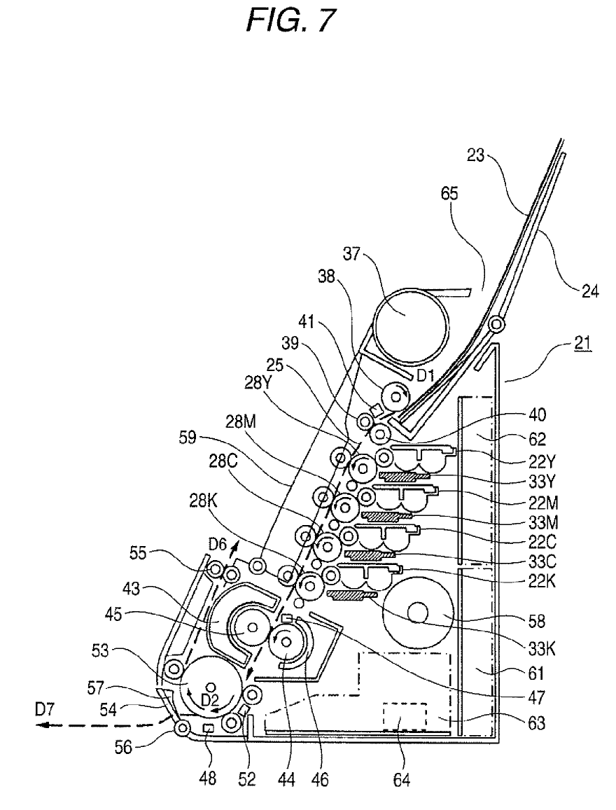

87 represents a timing generating part. It generates a control signal related to the timing for driving the organic electroluminescence elements 1 formed on the light emitting element substrate 70. The image data stored in the image memory 85, and the light amount correction data stored in the light amount correction data memory 86 (or previously duplicated in another high-speed memory not shown) are supplied to the light emitting element substrate 70 via a cable 76, a connector B 73b, a relay substrate 72, a connector A 73a, and a FPC 80 described later by reference to FIG. 6 based on the clock signals, the line synchronization signals, and the like generated from the timing generating part 87.

Further, the image data and the timing signals supplied to the light emitting element substrate 70 are supplied to the TFT circuit 82 by, for example, a wiring in which a metal layer is formed on ITO formed on the light emitting element substrate 70. In addition, the light amount correction data and the timing signals are also supplied similarly to the source driver 81.

Incidentally, the TFT circuit 82 is broadly divided into the pixel circuit 89 and the gate controller 88. The pixel circuits 89 are provided one for each organic electroluminescence element 1. The organic electroluminescence elements 1 for M pixels are defined as one group, and N groups thereof are provided on the light emitting element substrate 70. In Example 1 640 groups are provided, where each group corresponds to 8 pixels (i.e., M=8). Accordingly, the total number of pixels is 8×640=5120 pixels. Each pixel circuit 89 has a driver part 90 for supplying a current to the organic electroluminescence element 1, and driving it, and a so-called current program part 91 for storing the current value (i.e., the driving current value of the organic electroluminescence element 1) supplied from the driver for controlling the lighting of the organic electroluminescence element 1 in a capacitor included therein. Thus, it can constant-current drive the organic electroluminescence element 1 according to the driving current value previously programmed at a prescribed timing.

The gate controller 88 includes a shift register for sequentially shifting the received binary image data, a latch part provided in parallel with the shift register and for holding these all together after the completion of input of a prescribed number of pixels into the shift register, and a control part for controlling the timing of these operations (all not shown). Further, the gate controller 88 outputs SCAN_A and SCAN_B signals, and thereby controls the timings of the period for effecting ON/OFF of the organic electroluminescence element 1 connected to the pixel circuit 89, and the current program period for setting the driving current.

On the other hand, the source driver 81 has D/A converters 92 the number of which corresponds to the number N of groups of the organic electroluminescence elements 1 (640 in Example 1) in the inside thereof. The source driver 81 sets the driving currents of individual organic electroluminescence elements 1 based on the light amount correction data (e.g., 8 bit) supplied via the FPC 80, and thereby controls the light emission luminances of respective organic electroluminescence elements 1 so as to be generally equal one another.

Then, the size of the light emitting element substrate 70 will be described by reference to FIGS. 5, 4A and 4B, and 2 in combination.

Incidentally, in an exposure apparatus mounting therein the light emitting element substrate 70, as already described, 5120 organic EL elements 63 are required in order to obtain an A4-size (about 21-millimeter) exposure region at a resolution of 600 dpi along the main scanning direction. The TFT circuit 82 for driving these pixels has a scale of about 500000 gates according to the study of the present inventors. When this is formed with a process rule of 4.5 micrometers, the shift register, the latch part, and other control type circuits included in the gate controller 88 have a width of about 1000 micrometers, and the pixel circuit 89 has a width of 200 micrometers. Thus, this much length is necessary along the sub-scanning direction. The wiring from the source driver 81 to the pixel circuit 89 can be controlled to 1500 micrometers by, for example, achieving the routing in the intermediate layer 105 (see, FIG. 1) on which the TFT circuit 82 is formed in a multi layer structure.

A total of these can lead to a width of the TFT circuit along the sub-scanning direction of about 2700 micrometers. Namely, the TFT circuit 82 is, in FIG. 4B, formed with a width of 2700 micrometers in the direction of from the organic electroluminescence element 1 to the contact hole 110.

Incidentally, as described by reference to FIG. 2, in the light emitting element substrate 70 of Example 1, a 2000-micrometer sealing margin Lf exhibits a sufficient sealing performance. Therefore, when the sealing margin Lf in the direction of from the organic electroluminescence element 1 to the light amount sensor unit 77 is also assumed to be 2000 micrometers as shown in FIGS. 4A and 4B, the width along the sub-scanning direction in which either of the TFT circuit 82 and the sealing margin LF is present is about 4700 micrometers. When the region of the external wiring 120 shown in FIGS. 4A and 4B is added thereto, the size along the sub-scanning direction of the light emitting element substrate 70 can be implemented to be about 5 millimeters.

On the other hand, the width in the sub-scanning direction of the source driver 81 can be controlled to be about 3000 micrometers when 640 D/A converters 72 are mounted therein (the width along the main scanning direction is about 16000 micrometers). As already described, the source driver 81 is mounted at the position on the extension of the light emitting element rows in the light emitting element substrate 70. Therefore, no restriction is imposed on the size along the sub-scanning direction of the light emitting element substrate 70.

From the foregoing description, the light emitting element substrate 70 of Example 1 has a very small size along the sub-scanning direction. As described later, the size of the exposure apparatus becomes small, which further enables the reduction of the size of an image forming apparatus.

<Exposure Apparatus>

FIG. 6 is a view of a configuration of an exposure apparatus mounting therein the light emitting element substrate 70 of Example 1. Below, the structure of the exposure apparatus will be described in details by reference to FIG. 6.

In FIG. 6, 33 represents the exposure apparatus mounted in the image forming apparatus, in which the already described light emitting element substrate 70 is mounted. On the light emitting element substrate 70, light emitting elements, i.e., organic electroluminescence elements 1 (see, FIG. 1) as exposure light sources are formed at a resolution of 600 dpi (dot per inch) along the direction perpendicular to the drawing (main scanning direction).

71 represents a lens array in which bar lenses (non shown) formed of plastic or glass are arranged in rows. It guides the emission light from the organic electroluminescence element 1 formed on the light emitting element substrate 70 as an erect equimagnification image onto the surface of a photoreceptor on which a latent image is formed. The positional relationship among the light emitting element substrate 70, the lens array 71, and the photoreceptor 28 is adjusted so that one focus of the lens array 71 is on the side A of the substrate 2 forming the light emitting element substrate 70, and so that another focus thereof is on the surface of the photoreceptor 28. Namely, it is set such that L1=L2, where L1 represents the distance between the side A of the substrate 2 and the closer side of the lens array 71, and L2 represents the distance between the other side of the lens array 71 and the surface of the photoreceptor 28.

72 represents a relay substrate using, for example, a glass epoxy substrate. 73a represents a connector A, and 73b represents a connector B. The relay substrate 72 includes at least the connector A 73a and the connector B 73b mounted thereon. The relay substrate 72 once relays the image data, the light amount correction data, and other control signals externally supplied to the exposure apparatus by a cable 76 such as a flexible flat cable via the connector B 73b, and passes these signals to the light emitting element substrate 70.

Direct mounting of a connector on the surface of the substrate 2 forming the light emitting element substrate 70 is difficult in view of the junction strength and the reliability in various environments in which the exposure apparatus 33 is set. Therefore, in Example 1, the following configuration is achieved. As a connecting means of the connector A 73a of the relay substrate 72 and the light emitting element substrate 70, a FPC (flexible printed circuit) is adopted (not shown). For the junction of the light emitting element substrate 70 and the FPC, direct connection to, for example, an ITO (indium tin oxide) electrode previously formed on the light emitting element substrate 70 is implemented using, for example, an ACF (anisotropic conductive film).

On the other hand, the connector B 73b is a connector for connecting the exposure apparatus 33 with the outside. In general, connection with an ACF or the like often becomes a problem in terms of the junction strength. However, by providing the connector B 73b for a user to connect the exposure apparatus 33 onto the relay substrate 72, it is possible to ensure enough strength of an interface to which a user directly accesses.

74a represents a housing A, and obtained by forming a metal plate with, for example, folding. At the side of the housing A 74a opposing the photoreceptor 28, an L-shaped site 75 is formed. The light emitting element substrate 70 and the lens array 71 are disposed along the L-shaped site 75. The end face of the housing A 74a on the photoreceptor 28 side and the end face of the lens array 71 are aligned along the same plane, and further one edge of the light emitting element substrate 70 is supported by the housing A 74a. With this configuration, the forming precision of the L-shaped site 75 is ensured. This enables precise alignment of positional relationship formed between the light emitting element substrate 70 and the lens array 71. Thus, the housing A 74a is required to have dimensional precision. Therefore, it is desirably formed of a metal. Further, by forming the housing A 74a of a metal, it is possible to suppress the effect of noise on the control circuit using the TFT or the like formed on the light emitting element substrate 70, and electronic components such as IC chips to be surface mounted on the light emitting element substrate 70.

74b represents a housing B obtained by forming a resin. A notch (not shown) is provided in the vicinity of the connector B 73b of the housing B 74b. This enables a user to access the connector B 73b through the notch. Image data, light amount correction data, control signals such as clock signals and line synchronization signals, driving power for the control circuit, the driving power for the organic electroluminescence element which is a tight emitting element are supplied from the outside of the exposure apparatus 33 via the cable 76 connected to the connector B 73b to the exposure apparatus 33.

Incidentally, as already described in <Lighting control of organic electroluminescence element and size of light emitting element substrate>, the width along the sub-scanning direction of the light emitting element substrate 70 (see, FIG. 4A) of Example 1 can be set at about 5 millimeters. Therefore, the thickness Z of the exposure apparatus 33 including the light emitting element substrate 70 can be set at 7 millimeters or less by setting the wall thickness of the housing A 74a and the housing B 74b at a little less than 1 millimeter.

<Configuration of Image Forming Apparatus>

FIG. 7 is a view of a configuration of an image forming apparatus mounting therein the exposure apparatus 33 applying the light emitting element substrate 70 of Example 1 of the invention.

In FIG. 7, an image forming apparatus 21 is configured as follows: in the apparatus, development stations for four colors of a yellow development station 22Y, a magenta development station 22M, a cyan development station 22C, and a black development station 22K are arranged stepwise in the longitudinal direction; above this, a paper feed tray 24 in which recording paper sheets 23 are accommodated is disposed; and a recording paper transfer path 25 serving as a transfer path for the recording paper sheets 23 fed from the paper feed tray 24 is disposed at the sites corresponding to the respective development stations 22Y to 22K in the longitudinal direction from above to below.

The development stations 22Y to 22K are the ones for forming yellow, magenta, cyan, and black toner images, respectively, sequentially from the upstream side of the recording paper transfer path 25. The yellow development station 22Y includes a photoreceptor 28Y; the magenta development station 22M includes a photoreceptor 28M; the cyan development station 22C includes a photoreceptor 28C; and the black development station 22K includes a photoreceptor 28K. Further, each of the development stations 22Y to 22K includes therein members for implementing a series of development processes in electrophotography such as a development sleeve and a charger not shown.

Further, under the respective development stations 22Y to 22K, exposure apparatuses 33Y, 33M, 33C, and 33K for exposing the surfaces of the photoreceptors 28Y to 28K to light, and forming electrostatic latent images are disposed, respectively.

Incidentally, the development stations 22Y to 22K are different from one another in charged developer color, but are equal to one another in configuration regardless of the development color. Therefore, for simplification of the following description, a description will be given without demonstrating a specific color, like the development station 22, the photoreceptor 28, and the exposure apparatus 33, except for the case where there is a particular need therefor.

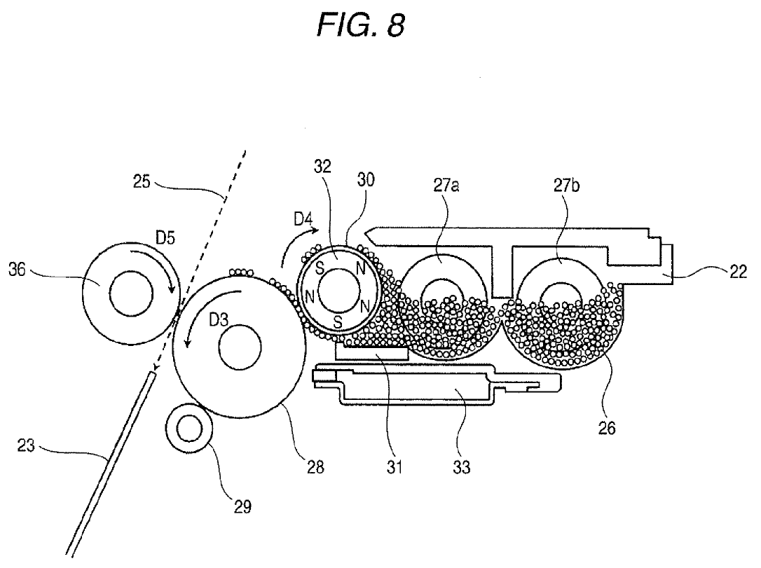

FIG. 8 is a view of a configuration showing the periphery of the development station 22 in the image forming apparatus 21 of Example 1 of the invention. In FIG. 8, in the inside of the development station 22, a developer 26 which is a mixture of carriers and a toner is charged. 27a and 27b represent stirring paddles for stirring the developer 26. With the rotation of the stirring paddles 27a and 27b, the toner in the developer 26 is charged to a prescribed electric potential through friction with carriers, and circulates in the inside of the development station 22, so that the toner and the carriers are sufficiently stirred and mixed. The photoreceptor 28 rotates in the direction D3 by a driving source not shown. 29 represents a charger, and charges the surface of the photoreceptor 28 to a prescribed electric potential. 30 represents a development sleeve, and 31 represents a thin layer forming blade. The development sleeve 30 has a magnet roll 32 including a plurality of magnet poles formed in the inside thereof. The layer thickness of the developer 26 supplied to the surface of the development sleeve 30 is regulated by the thin layer forming blade, and the development sleeve 30 rotates in the direction D4 by a driving source not shown. This rotation and the action of magnetic poles of the magnet roll 32 cause the developer 26 to be fed onto the surface of the development sleeve 30. Then, the electrostatic latent image formed on the photoreceptor 28 is developed by an exposure apparatus described later, and the developer 26 not transferred onto the photoreceptor 28 is recovered into the inside of the development station 22.

33 represents the already described exposure apparatus. As already described, the light emitting element substrate 70 (see, FIG. 4) mounted in the exposure apparatus 33 has an excellent sealing performance, and can form a latent image over a long period with stability. Therefore, it has a long product life as the exposure apparatus, and further, it can provide an electrostatic latent image in a desirable shape over a long period. For this reason, it can invariably form a high quality image.

Incidentally, as already described, the exposure apparatus 33 in Example 1 is formed such that the organic electroluminescence elements 1 are linearly arranged at a resolution of 600 dpi (dot per inch). It forms an electrostatic latent image of A4 size at most by selectively turning ON/OFF the organic electroluminescence elements according to the image data, on the photoreceptor 28 charged to a prescribed electric potential by the charger 29. Onto the electrostatic latent image portion, only the toner of the developer 26 fed to the surface of the development sleeve 30 is deposited. As a result, the electrostatic latent image is developed into an image.

At the position opposing the photoreceptor 28 across the recording paper transfer path 25, a transfer roller 36 is provided, and it rotates in the direction D5 by a driving source not shown. The transfer roller 36 is applied with a prescribed transfer bias, and transfers the toner image formed on the photoreceptor 28 onto the recording paper sheet 23 transferred along the recording paper transfer path 25.

Below, a description will be continued by reference back to FIG. 7.

As described up to this point, the image forming apparatus 21 in Example 1 is a tandem type color image forming apparatus in which a plurality of the development stations 22Y to 22K are arranged stepwise in the longitudinal direction It aims to have the same class size as that of a color ink jet printer. In the development stations 22Y to 22K, a plurality of units are arranged, respectively. Therefore, the reduction of size of the image forming apparatus 21 requires the following: with the reduction of size of the development stations 22Y to 22K themselves, the members involved in the image forming process disposed in the periphery of each of the development stations 22Y to 22K is reduced in size, and the disposition pitch of the development stations 22Y to 22K is minimized.

In view of the ease of use of a user, particularly, the accessibility to a recording paper sheet 23 for paper feed or for paper discharge when the image forming apparatus 21 is set at a desktop in an office or the like, the height from the bottom side to a paper feed port 65 of the image forming apparatus 21 is desirably set at 250 millimeters or less. In order to implement this, the height of the whole development stations 22Y to 22K is required to be controlled to about 100 millimeters in the overall configuration of the image forming apparatus 21. However, for example, an existing LED head has a thickness of about 15 millimeters. When this is mounted between the development stations 22Y to 22K, it is difficult to achieve the target. According to the result of the study by the present inventors, assuming that the thickness of the exposure apparatus 33 is set at 7 millimeters or less, it is possible to control the height of the whole development stations to 100 millimeters or less even when the exposure apparatuses 33Y to 33K are disposed in the gaps between the development stations 22Y to 22K. As described in <Exposure apparatus>, the thickness Z of the exposure apparatus of Example 1 is less than 7 millimeters. Therefore, it is possible to set the height of the whole development stations at 100 millimeters or less, and to configure a very compact image forming apparatus 21.

37 represents a toner bottle, in which yellow, magenta, cyan, and black toners are stored. Toner transfer pipes not shown are set between the toner bottle 37 and respective development stations 22Y to 22K, through which toners are fed to the development stations 22Y to 22K, respectively.

38 represents a paper feed roller. It rotates in the direction D1 by controlling an electromagnetic clutch not shown, and feeds paper sheets 23 loaded in the paper feed tray 24 to the recording paper transfer path 25.

At the recording paper transfer path 25 situated between the paper feed 25 roller 38 and the transfer site of the most upstream yellow development station 22Y, there are provided a pair of a resist roller 39 and a pinch roller 40 as nip transfer means on the inlet side The pair of the resist roller 39 and the pinch roller 40 temporarily stops the recording paper sheet 23 transferred by the paper feed roller 38, transfers it in the direction of the yellow development station 22Y at a prescribed timing. By the temporary stopping, the tip of the recording paper sheet 23 is regulated to be in parallel with the axial direction of the pair of the resist roller 39 and the pinch roller 40. This prevents the recording paper sheet 23 from obliquely going.

41 represents a recording paper passage detection sensor. The recording paper passage detection sensor 41 is formed of a reflection type sensor (photoreflector). It detects the front end and the rear end of the recording paper sheet 23 by whether reflection light is present or not.

Incidentally, upon start of rotation of the resist roller 39 (for which the power transfer is controlled by an electromagnetic clutch not shown to turn the rotation ON/OFF), the recording paper sheet 23 is transferred along the recording paper transfer path 25 in the direction of the yellow development station 22Y. Thus, the writing timings of the electrostatic latent images by the exposure apparatuses 33Y to 33K disposed in the vicinity of respective development stations 22Y to 22K are independently controlled at the timing of start of rotation of the resist roller 39 as the starting point.

At the recording paper transfer path 25 situated on the further downstream side of the most downstream side black development station 22K, a fixer 43 is provided as a nip transfer means on the outlet side. The fixer 43 is formed of a heating roller 44 and a pressure roller 45. The heating roller 44 is a roller of a multilayered structure formed of a heating belt, a rubber roller, and a core material (all not shown) in the order closer to the surface. Out of these, the heating belt is a belt further having a 3-layer structure. It is formed of a releasing layer, a silicon rubber layer, and a base material layer (all not shown) from the closer side to the surface. The releasing layer is formed of a fluororesin with a thickness of about 20 to 30 micrometers, and it imparts the releasing property to the heating roller 44. The silicon rubber layer is formed of an about 170-micrometer silicon rubber, and it imparts appropriate elasticity to the pressure roller 45. The base material layer is formed of a magnetic material which is an alloy of iron/nickel/chromium, or the like.

46 represents a back core including therein an excitation coil. It is formed as follows: in the inside of the back core 46, an excitation coil including a prescribed number of bound surface-insulated wire rods made of copper (not shown) is drawn in the direction of rotation axis of the heating roller 44, and extends along the circumferential direction of the heating roller 44 at the opposite ends of the heating roller 44. When the excitation coil is applied with an alternating current of about 30 kHz from an exciting circuit (not shown) which is a semi-resonance type inverter, a magnetic flux occurs in the magnetic path formed of the back core 46 and the base material layer of the heating roller 44. With this magnetic flux, an eddy current is formed in the base material layer of the heat generating belt of the heating roller 44. The heat generated in the base material layer is transferred to the releasing layer through the silicon rubber layer, so that the surface of the heating roller 44 generates heat.

47 represents a temperature sensor for detecting the temperature of the heating roller 44. The temperature sensor 47 is a ceramic semiconductor obtained from high temperature sintering by using a metal oxide as a main raw material. It changes in load resistance according to the temperature. By applying this, it can measure the temperature of an object with which it is in contact. The output from the temperature sensor 47 is inputted to a control apparatus not shown. The control apparatus controls the electric power outputted to the excitation coil in the inside of the back core 46 based on the output from the temperature sensor 47, and controls the surface temperature of the heating roller 44 so as to be about 170° C.

When the recording paper sheet 23 having a toner image formed thereon passes through the nip portion formed by the temperature-controlled heating roller 44 and the pressure roller 45, the toner image on the recording paper sheet 23 is heated and pressurized by the heating roller 44 and the pressure roller 45, respectively. As a result, the toner image is fixed on the recording paper sheet 23.

48 represents a recording paper rear end detection sensor, which monitors the state in which the recording paper sheet 23 is discharged. 52 represents a toner image detection sensor. The toner image detection sensor 52 is a reflection type sensor unit using a plurality of light emitting elements (all for visible light) different in emission spectrum, and a single light receptive element. It detects the image density utilizing the following fact: the absorption spectrum varies according to the image color between at the surface and at the image-formed portion of the recording paper sheet 23. Further, the toner image detection sensor 52 can detect not only the image density but also the image-formed position. Therefore, in the image forming apparatus 21 in Example 1, the toner image detection sensors 52 are provided at two positions along the direction of width of the image forming apparatus 21. Thus, the image forming timing is controlled based on the detected position of the image misregistration amount detection pattern formed on the recording paper sheet 23.

53 is a recording paper transfer drum. The recording paper transfer drum 53 is a roller made of a metal, the surface of which is covered with a rubber having a thickness of about 200 micrometers. The recording paper sheet 23 after fixing is transferred in the direction D2 along the recording paper transfer drum 53. At this step, the recording paper sheet 23 is cooled by the recording paper transfer drum 53, and bent in the opposite direction from the image-formed side to be transferred. This can largely reduce the curling generated in the case where a high density image is formed on the entire surface of the recording paper sheet, or the like. Thereafter, the recording paper sheet 23 is transferred in the direction D6 by a kickout roller 55, and discharged to a discharge tray 59.

54 is a face-down discharge part. The face-down discharge part 54 is formed rotatably about a support member 56. When the face-down discharge part 54 is set in the open state, the recording paper sheet 23 is discharged in the direction D7. The face-down discharge part 54 includes a rib formed along the transfer path at the back so as to guide the transfer of the recording paper sheet 23 with the recording paper transfer drum 53 in the close state.

58 represents a driving source. In Example 1, a stepping motor is adopted. By the driving source 58, the periphery of the respective development stations 22Y to 22K including the paper feed roller 38, the resist roller 39, the pinch roller 40, the photoreceptors (28Y to 28K), and transfer rollers (36Y to 36K), the fixer 43, the recording paper transfer drum 53, and the kickout roller 55 are driven.

61 represents a controller It receives the image data from a computer not shown via an external network, and develops and generates a printable image data.

62 represents an engine control part. The engine control part 62 controls the hardware and the mechanism of the image forming apparatus 21, and forms a color image on a recording paper sheet 23 based on the image data transferred from the controller 61. In addition, it carries out the overall control of the image forming apparatus 21.

63 represents a power source part. The power source part 63 supplies a power of a prescribed voltage to the exposure apparatuses 33Y to 33K, the driving source 58, the controller 61, and the engine control part 62. In addition, it supplies power to the heating roller 44 of the fixer 43. Whereas, a so-called high voltage power system for charging of the surface of the photoreceptor 28, the development bias to be applied to the development sleeve (see a reference numeral 30 in FIG. 7), a transfer bias to be applied to the transfer roller 36, or the like is also included in the power source part.

Further, the power source part 63 includes therein a power monitoring part 64, so that at least the power supply voltage supplied to the engine control part 62 can be monitored. The monitor signal is detected at the engine control part 62, thereby to detect the reduction of the power supply voltage occurred upon off of a power switch or power failure.

In the above description, the case where the invention is applied to a color image forming apparatus was described. However, the invention can also be applied to an image forming apparatus of a monochromatic color such as black. Further, when the invention is applied to a color image forming apparatus, the development colors are not limited to the four colors of yellow, magenta, cyan, and black.

### Example 2

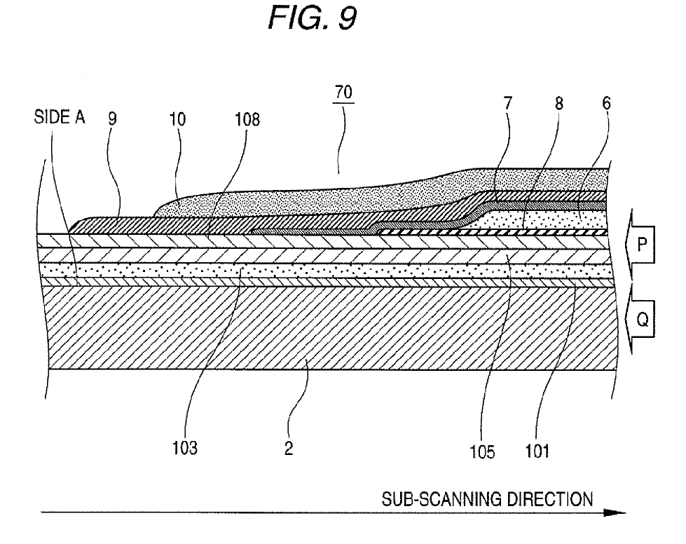

FIG. 9 is a cross sectional view showing a configuration of a light emitting element substrate 70 in Example 2 of the invention.

Below, the configuration of the light emitting element substrate 70 of Example 2 will be described by reference to FIG. 9 Incidentally, for the light emitting element substrate 70, an exposure apparatus applying the light emitting element substrate 70, and an image forming apparatus mounting the exposure apparatus therein, to be described in Example 2, the description on the common portions to those in Example 1 is omitted.

FIG. 9 is a drawing corresponding to FIG. 2 in the description of Example 1. In Example 1 (FIG. 2), there is adopted a configuration in which a part of the pixel regulating part 8 is covered with the cathode 7. However, in Example 2 (FIG. 9), there is adopted a configuration in which the cathode 7 covers the wider region than the pixel regulating part 8 so that the cathode 7 is in contact with the TFT protective layer 108.

The light emitting element substrate 70 in Example 2 is also configured to have a substrate 2, a plurality of light emitting parts (see, the already described light emitting parts LS, FIG. 1) including a polymer organic electroluminescence material formed on the substrate, an electrode 7 covering the light emitting parts LS, and a sealing part 10 including a thermosetting resin, and covering at least the wider region than this electrode 7. The functions and advantages thereof are almost the same as those described in Example 1, but are different from Example 1 in terms of the fact that the pixel regulating layer 8 is formed of a resin such as polyimide in Example 2.

When a resin such as polyimide is used as the pixel regulating part 8, the pixel regulating part 8 is formed in the following manner. After the formation of the TFT protective layer 108 on the substrate 2, an about 1-micrometer insulating material including, for example, photosensitive polyimide is coated on the entire surface of the light emitting element substrate 70 with a spin coating method, and patterned into a prescribed shape with a photolithography method. When a water repellent material such as polyimide is adopted as the pixel regulating part 8, the following procedure is desirable. After the formation of the pixel regulating part 8, the surface is subjected to an ultraviolet irradiation treatment or a plasma treatment, thereby to be roughened to a surface roughness Ra of about 5 nanometers. Thus, it is processed so as to have a high wettability to a solvent such as toluene or xylene dissolving the polymer organic electroluminescence material, or a solution containing the polymer organic electroluminescence material dissolved therein. This configuration results in the reduction of ununiform coating of the polymer organic electroluminescence material coated with a spin coating method or the like. As a result, the distribution of light emission luminances at the light emitting parts LS of the organic electroluminescence elements 1 (see, FIG. 1) are made uniform.

For the pixel regulating part 8, there can be also used, other than the polyimide, a polymer material having, as the main chain, a vinyl group, water absorbing silicone, isocyanate, a polyester polymer, polyamide, a fluorine-containing polymer, or an epoxy group, or at the end, a vinyl group, a glycidyl group, or an aryl group.

Incidentally, after the formation of the pixel regulating layer 8: as described in <Light emitting layer>, a polymer organic electroluminescence material is coated onto the light emitting element substrate 82. Then, unnecessary regions are wiped off. Then, the cathode 7 is formed according to the material and the manufacturing method described in <Cathode>. A resin material such as polyimide allows moisture to permeate therethrough although in a small amount. Therefore, when a resin is used for the pixel regulating layer 8, it is possible to improve the barrier property against moisture or a gas by entirely covering the pixel regulating layer 8 by the cathode 7 made of a metal material such as Al.

### Example 3

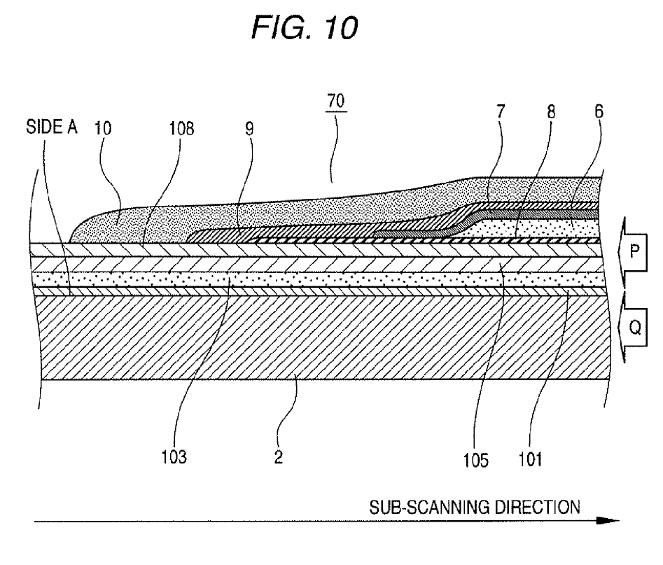

FIG. 10 is a cross sectional view showing a configuration of the light emitting element 70 in Example 3 of the invention.

Below, by reference to FIG. 10, the configuration of the light emitting element substrate 70 of Example 3 will be described. Incidentally, for the light emitting element substrate 70, an exposure apparatus applying the light emitting element substrate 70, and an image forming apparatus mounting the exposure apparatus therein, to be described in Example 3, the description on the common portions to those in Example 1 is omitted.

FIG. 10 is a drawing corresponding to FIG. 2 in the description of Example 1. As shown, the light emitting element substrate 70 in Example 3 is configured as follows. It has a substrate 2, a plurality of light emitting parts (see, the already described light emitting parts LS, FIG. 1) including a polymer organic electroluminescence material formed on the substrate, an electrode (cathode 7) covering the light emitting parts LS, and a sealing part 10 including a thermosetting resin, and covering at least the wider region than this electrode (cathode 7). Further, the protective part 9 covering at least the wider region than the electrode (cathode 7) is formed between the electrode (cathode 7) and the sealing part 10. In addition, the sealing part including a thermosetting rein covers the wider region than the protective part 9.

At this step, the periphery of the sealing part 10 comes in contact with the TFT protective layer 108. As described in <TFT>, the TFT protective layer 108 forms a dense film of silicon nitride or the like, and further it is formed with a thickness of at least about 300 nanometers. Therefore, the surface is in an unevenness-free uniform state. This enables the adhesion without a gap between the periphery of the sealing part 10 and the TFT protective layer 108.

Incidentally, in Example 3, 9 is a protective part formed of a hygroscopic material such as aluminum oxide or calcium oxide. The protective part 9 is a film-like structure having a thickness of at least 50 nanometers, and it can be formed with, for example, a sputtering method.

The protective part 9 is desirably formed so as to cover not only the light emitting parts LS of the organic electroluminescence element 1 (see, FIG. 1), but also the entire surface of the cathode 7 thereof.

The protective part 9 formed of a hygroscopic material is entirely covered with the sealing part 10 including a thermosetting resin. Therefore, the protective part 9 is not directly exposed to the air. The amount of the moisture permeating through the sealing part 10 is very small. Therefore, the protective part 9 can exhibit the hygroscopic effect even with a thickness of about 50 nanometers.

Incidentally, when the tight emitting element substrate 70 of the invention is applied to an exposure apparatus, the light emitting element substrate 70 is not required to have flexibility. Therefore, basically, the protective part 9 may be properly formed as thick as, for example, about 10 micrometers when time constraints in the manufacturing step permit. By increasing the thickness of the protective layer 9 in this manner, the difference in level due to the underlying structures covered with the protective layer 9, or the like is absorbed with reliability. Resultantly, the surface of the protective part 9 comes in an unevenness-free uniform state. In addition, it is possible to achieve a very advantageous state that the hygroscopic material can be increased.

Further, it is, of course, possible to configure the protective part 9 in a multilayer of the hygroscopic material and the metal oxide or metal nitride described in Example 1. In this case, there is adopted a configuration in which the layer of the hygroscopic material is entirely covered with the layer of the metal oxide or the metal nitride, which enables the further improvement of the barrier property against moisture or a gas.

### Example 4

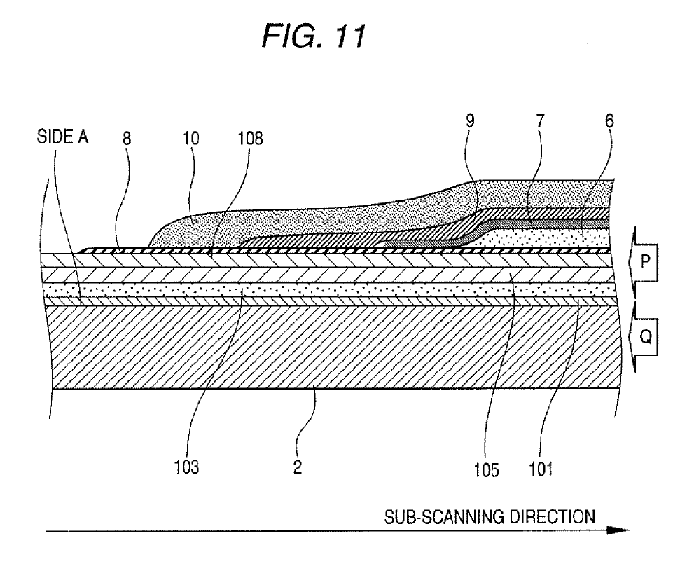

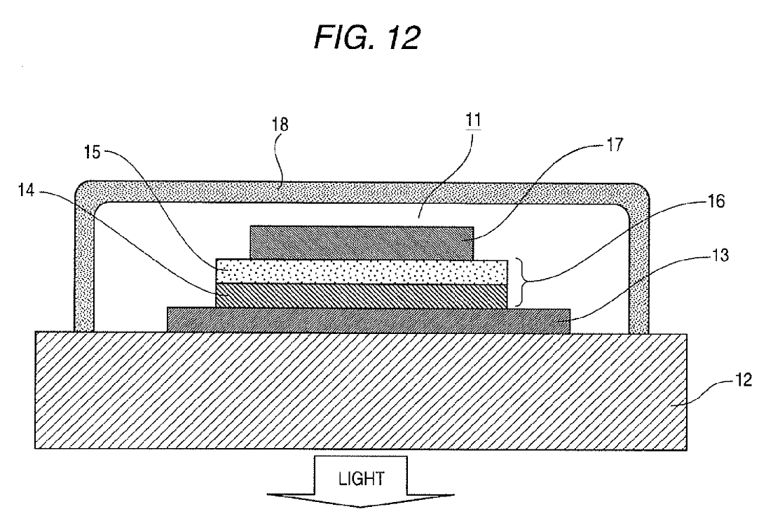

FIG. 11 is a cross sectional view showing a configuration of the light emitting element 70 in Example 4 of the invention.

Below, by reference to FIG. 11, the configuration of the light emitting element substrate 70 of Example 4 will be described. Incidentally, for the light emitting element substrate 70, an exposure apparatus applying the light emitting element substrate 70, and an image forming apparatus mounting the exposure apparatus therein, to be described in Example 4, the description on the common portions to those in Example 1 is omitted.

FIG. 11 is a drawing corresponding to FIG. 2 in the description of Example 1 As shown, the light emitting element substrate 70 in Example 4 is configured as follows. It has a substrate 2, a plurality of light emitting parts (see, the already described light emitting parts LS, FIG. 1) including a polymer organic electroluminescence material formed on the substrate, an electrode (cathode 7) covering the light emitting parts LS, and a sealing part 10 including a thermosetting resin, and covering at least the wider region than this electrode (cathode 7). Further, it has a pixel regulating part 8 for regulating the light emitting region of each light emitting parts LS on the substrate 2. Thus, the outer peripheral portion of the sealing part 10 including a thermosetting resin is bonded with the pixel regulating part 8.

In Example 4, 8 represents a pixel regulating part for regulating the position, shape, size, and the like of the light emitting part LS contributing to light emission by covering a part of the anode 3. The pixel regulating part 8 is, as described in details in <Pixel regulating part>, a film-like structure formed of silicon nitride or silicon oxide with a thickness of 50 nanometers to 2 micrometers. As shown, the pixel regulating part 8 is formed on the TFT protective layer 108. However, as described in <TFT>, the TFT protective layer 108 is also formed of a dense material such as silicon nitride or silicon oxide, and has a thickness of about 300 nanometers. Thus, by further providing the pixel regulating part 8 having a similar dense structure on the TFT protective layer 108, it is possible to form the surface of the pixel regulating part 8 into an unevenness-free uniform state. Therefore, the sealing part 10 including a thermosetting resin formed on the pixel regulating part 8 is bonded with the pixel regulating part 8 without a gap. This can keep the barrier property against moisture or a gas at a very high level.

In Example 4, as the pixel regulating part 8, silicon nitride or silicon oxide is used, but as the pixel regulating part 8, for example, it is also possible to use a resin material such as polyimide as shown in Example 2. However, in this case, in order to ensure the sealing performance, it is desirable to form the pixel regulating part 8 so as to be entirely covered with the sealing part 10.

A light emitting apparatus of the invention, and an exposure apparatus using the same, and an image forming apparatus can surely protect the organic electroluminescence element from the moisture or gases in an external atmosphere regardless of the simple configuration, and can effectively prevent the shrinking or the occurrence and expansion of dark spots. Therefore, these can be utilized in various apparatuses necessary for obtaining stable light emission over a long period. For example, these are applicable to a copying machine, a multifunction printer, a printer, a facsimile, or the like. Further, the organic electroluminescence element can provide three primary colors of Red, Green, and Blue according to selection of the organic light emitting material. Therefore, for example, when an exposure apparatus for carrying out exposure to each color of R, G, and B is used, it can also be applied to an image forming apparatus of a type which directly exposes a photographic paper to light. Further, the light emitting apparatus of the invention is not only applicable to an exposure apparatus or an image forming apparatus, but also applicable to all the light emitting apparatuses, for example, a monitor apparatus such as a display, which includes light emitting elements such as organic electroluminescence elements formed therein, and requires sealing.

This application is based upon and claims the benefit of priority of Japanese Patent Application No2005-300039 filed on Oct. 14, 2005, the contents of which is incorporated herein by references in its entirety.

What is claimed is:

1. A light emitting apparatus, comprising:
a substrate;
a plurality of light emitting parts formed by the use of a polymer organic electroluminescence material on the substrate;
an electrode covering the light emitting parts; and
a sealing part including a thermosetting resin and covering at least a wider region than the electrode.

2. The light emitting apparatus according to claim 1, comprising:
a protective part covering at least the entire surface of the electrode formed between the electrode and the sealing part;
wherein the outer peripheral portion of the sealing part is configured so as to be bonded to the protective part.

3. The light emitting apparatus according to claim 2, comprising:
on the substrate, a wiring part for inputting a control signal involved in driving of at least the light emitting parts; wherein the protective part is configured so as to cover the wiring part, and the sealing part is configured so as to be bonded to the protective part.

4. The light emitting apparatus according to claim 2, comprising:
a pixel regulating part for regulating a light emitting region of each of the light emitting parts on the substrate, wherein the pixel regulating part and the protective part include the same material.

5. The light emitting apparatus according to claim 4, wherein the protective part and the pixel regulating part include a metal oxide or a metal nitride.

6. The light emitting apparatus according to claim 1 comprising:
a protective part covering at least a wider region than the electrode formed between the electrode and the sealing part, wherein the sealing part is configured so as to cover a wider region than the protective part.

7. The light emitting apparatus according to claim 6, wherein the protective part includes a hygroscopic material.

8. The light emitting apparatus according to claim 1, comprising:
a pixel regulating part for regulating a light emitting region of each of the light emitting parts on the substrate, wherein the outer peripheral portion of the sealing part is configured so as to be bonded to the pixel regulating part.

9. The light emitting apparatus according to claim 1, wherein the sealing part includes an epoxy type resin with a glass transition temperature of 140° C. to 180° C.

10. The light emitting apparatus according to claim 1, wherein the sealing part is configured so as to contain an inorganic filler having a cleavage property.

11. The light emitting apparatus according to claim 1, comprising:
a driving circuit including a TFT for driving the light emitting parts provided on the substrate;
wherein the driving circuit is configured so as to be covered with the sealing part.

12. The light emitting apparatus according to claim 1 wherein the sealing part is configured so as to contain an inorganic porous material (zeolite) having a water absorbing property.

13. The light emitting apparatus according to claim 1, wherein the sealing part is configured so as to contain an inorganic porous material having a water absorbing property filled in an amount equal to or more than the amount of a filled inorganic filler having a cleavage property.

14. The light emitting apparatus according to claim 1, wherein the sealing part is configured to have a thickness of 50 micrometers or more.

15. An exposure apparatus characterized by mounting therein the light emitting apparatus according to claim 1,
wherein the plurality of the fight emitting parts are configured in a manner capable of being independently turned ON/OFF.

16. The exposure apparatus according to claim 15, wherein the light emitting parts are driven by an active matrix circuit provided on the substrate.

17. A method for manufacturing a light emitting apparatus, comprising the steps of:
forming a plurality of light emitting parts by the use of a polymer organic electroluminescence material on a substrate;
forming an electrode covering the light emitting parts; and
sealing at least a wider region than the electrode with a sealing part including a thermosetting resin.

18. The method for manufacturing a light emitting apparatus according to claim 17, including a step of:
after coating a polymer organic electroluminescence material on the substrate, removing at least the organic electroluminescence material at a position corresponding to the outer peripheral portion of the sealing part.

19. The method for manufacturing a light emitting apparatus according to claim 17, comprising a step of:
after coating a polymer organic electroluminescence material on the substrate, carrying out a heat treatment, wherein the temperature of the heat treatment is set higher than the temperature for curing the thermosetting resin later.

20. The method for manufacturing a light emitting apparatus according to claim 17, wherein in the step of sealing, at least two stages of curing temperatures are set, and the curing temperatures are set such that the latter curing temperature is higher.
